(19) United States
(12) Patent Application Publication
(10) Pub. No.: US 2026/0033089 A1
(43) Pub. Date: Jan. 29, 2026

(54) DISPLAY DEVICE AND ELECTRONIC DEVICE INCLUDING THE SAME

(71) Applicant: Samsung Display Co., Ltd., Yongin-si (KR)

(72) Inventors: Donghyun Kim, Yongin-si (KR); Chulkyu Kang, Yongin-si (KR); Sujin Kim, Yongin-si (KR); Seonkyoon Mok, Yongin-si (KR); Jaewon Park, Yongin-si (KR); Minwoo Byun, Yongin-si (KR); Kimyeong Eom, Yongin-si (KR); Kyonghwan Oh, Yongin-si (KR); Donghwan Jeon, Yongin-si (KR); Soohong Cheon, Yongin-si (KR)

(21) Appl. No.: 19/278,144

(22) Filed: Jul. 23, 2025

(30) Foreign Application Priority Data
Jul. 25, 2024 (KR) 10-2024-0098923
Nov. 1, 2024 (KR) 10-2024-0153712

(51) Int. Cl. H10H 29/49; H10H 29/34

(52) U.S. Cl. CPC H10H 29/49; H10H 29/34

(57) ABSTRACT

A display device include: a substrate including a display area and a non-display area, the display area including first regions and second regions; a gate driving circuit in the non-display area; a first write gate line extending in a first direction and electrically connected to the gate driving circuit; a second write gate line extending in the first direction through the first regions and the second regions and overlapping the first write gate line; first contact portions disposed between the first write gate line and the second write gate line and electrically connecting the first write gate line to the second write gate line; and pixels including subpixels in each of the first regions and each of the second regions, each of the subpixels electrically connected to the second write gate line, where the first contact portions are in the second regions, not in the first regions.

This application claims priority to Korean Patent Application No. 10-2024-0098923, filed on Jul. 25, 2024, and Korean Patent Application No. 10-2024-0153712, filed on Nov. 1, 2024, and all the benefits accruing therefrom under 35 U.S.C. § 119, the contents of which in their entirety are herein incorporated by reference.

### BACKGROUND

### 1. Field

One or more embodiments relate to a display device and an electronic device including the same.

### 2. Description of the Related Art

In recent years, electronic devices that include display devices have become more diverse in their uses. In addition, as electronic devices including display devices become thinner and lighter, the range of applications for such electronic devices is expanding.

As electronic devices including display devices are utilized in various ways, various methods of designing the shape of display devices have been researched, and also the number of functions that may be embedded with or linked to the display devices has increased.

### SUMMARY

One or more embodiments include a display device and an electronic device including the same, both of which have improved display quality. However, the embodiments are just examples and do not limit the scope of the disclosure.

Additional aspects will be set forth in part in the description which follows and, in part, will be apparent from the description, or may be learned by practice of the presented embodiments of the disclosure.

According to one or more embodiments, a display device includes: a substrate including a display area and a non-display area, where the display area includes a plurality of first regions and a plurality of second regions, and the non-display area surrounds at least a portion of the display area; a gate driving circuit disposed in the non-display area; a first write gate line extending in a first direction and electrically connected to the gate driving circuit; a second write gate line extending in the first direction through the first regions and the second regions and overlapping the first write gate line in a plan view; first contact portions disposed between the first write gate line and the second write gate line, and electrically connecting the first write gate line to the second write gate line; and pixels including subpixels arranged in each of the first regions and each of the second regions of the display area, each of the subpixels being electrically connected to the second write gate line, where the first contact portions is arranged in the second regions, not in the first regions.

In an embodiment, the first contact portions may be spaced apart from each of the first regions.

In an embodiment, the first contact portions may not overlap each of the first regions.

In an embodiment, the second regions may be spaced apart from the non-display area in the first direction, and at least one of the first regions may be located between the non-display area and the plurality of second regions.

In an embodiment, the first regions and the second regions may be arranged alternately along the first direction.

In an embodiment, each of the pixels may include a first subpixel, a second subpixel, and a third subpixel, a first subpixel circuit region, a second subpixel circuit region, and a third subpixel circuit region may be arranged adjacent to each other in the first direction, a first subpixel circuit of the first subpixel may be arranged in the first subpixel circuit region, a second subpixel circuit of the second subpixel may be arranged in the second subpixel circuit region, and a third subpixel circuit of the third subpixel may be arranged in the third subpixel circuit region, and the first contact portions may be arranged to correspond to each of the first subpixel circuit region, the second subpixel circuit region, and the third subpixel circuit region in each of the second regions.

In an embodiment, a width of one of the first regions in the first direction may be greater than a width of one of the second regions in the first direction.

In an embodiment, the number of pixels in each of the first regions may be greater than the number of pixels in each of the second regions.

In an embodiment, the display device may further include an insulating layer disposed between the first write gate line and the second write gate line, and the insulating layer may define contact holes therethrough, and the first contact portions may be arranged in the contact holes, respectively.

In an embodiment, the first write gate line may include a first lower write gate line and a first upper write gate line, and the first upper write gate line may be disposed on the first lower write gate line and overlap the first lower write gate line in the plan view.

In an embodiment, the display device may further include second contact portions disposed between the first lower write gate line and the first upper write gate line, and electrically connecting the first lower write gate line and the first upper write gate line, and the second contact portions may be disposed in each of the first regions and each of the second regions.

In an embodiment, the second write gate line may be disposed above the first write gate line.

In an embodiment, the second write gate line may be disposed below the first write gate line.

In an embodiment, each of the subpixels may include a data write transistor to which a data voltage is applied, and the second write gate line may be electrically connected to a gate electrode of the data write transistor.

In an embodiment, the display device may further include a data line extending along a second direction intersecting the first direction, the data line being electrically connected to the data write transistor.

According to one or more embodiments, a display device includes a substrate including a display area and a non-display area surrounding at least a portion of the display area, a gate driving circuit in the non-display area, a first write gate line extending in a first direction and electrically connected to the gate driving circuit, a second write gate line extending in the first direction and overlapping the first write gate line in a plan view, first contact portions disposed between the first write gate line and the second write gate line, and electrically connecting the first write gate line to the second write gate line, and pixels arranged in the display area, each pixels including subpixels, each of the subpixels being electrically connected to the second write gate line, where the number of the first contact portions is less than the number of the subpixels electrically connected to the second write gate line.

In an embodiment, the display area may include a plurality of first regions and a plurality of second regions, at least one of the pixels may be arranged in each of the first regions and each of the second regions, each of the first write gate line and the second write gate line may extend through the first regions and the second regions, and the first contact portions may be arranged in the second regions, not in the first regions.

In an embodiment, the second regions may be spaced apart from the non-display area in the first direction, and at least one of the first regions may be located between the non-display area and the plurality of second regions in the first direction.

In an embodiment, the first regions and the second regions may be arranged alternately along the first direction.

In an embodiment, each of the pixels may include a first subpixel, a second subpixel, and a third subpixel, a first subpixel circuit region, a second subpixel circuit region, and a third subpixel circuit region may be arranged adjacent to each other in the first direction, a first subpixel circuit of the first subpixel may be arranged in the first subpixel circuit region, a second subpixel circuit of the second subpixel may be arranged in the second subpixel circuit region, and a third subpixel circuit of the third subpixel may be arranged in the third subpixel circuit region, and the first contact portions may be arranged to correspond to each of the first subpixel circuit region, the second subpixel circuit region, and the third subpixel circuit region in each of the second regions.

According to one or more embodiments, an electronic device includes a processor, and a display device including a controller configured to receive a control signal from the processor and output a scan control signal based on the control signal. The display device includes a substrate including a display area and a non-display area, where the display area includes first regions and second regions, and the non-display area surrounds at least a portion of the display area, a gate driving circuit disposed in the non-display area, a first write gate line extending in a first direction and electrically connected to the gate driving circuit, a second write gate line extending in the first direction through the first regions and the second regions and overlapping the first write gate line in a plan view, first contact portions disposed between the first write gate line and the second write gate line, and electrically connecting the first write gate line to the second write gate line, and pixels including subpixels arranged in each of the first regions and each of the second regions of the display area, each of the subpixels being electrically connected to the second write gate line, where the first contact portions are arranged in the second regions, not in the first regions.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic perspective view of an electronic device according to an embodiment;

FIG. 1B is an exploded perspective view of an electronic device according to an embodiment;

FIG. 2 is a schematic block diagram of an electronic device according to an embodiment;

FIG. 3 is a schematic plan view of a display device according to an embodiment;

FIG. 4 is a schematic equivalent circuit diagram of a subpixel circuit of a subpixel of a display device and a light-emitting diode electrically connected to the subpixel circuit, according to an embodiment;

FIG. 5 is a schematic plan view of a display device according to an embodiment;

FIG. 6 is an enlarged plan view of a portion of a display device according to an embodiment;

FIG. 7 is a schematic cross-sectional view of the display device, taken along line I-I′ of FIG. 6;

FIG. 8 is a schematic cross-sectional view of the display device, taken along line I-I′ of FIG. 6;

FIG. 9 is a schematic cross-sectional view of the display device, taken along line I-I′ of FIG. 6;

FIG. 10 is a cross-sectional view of a portion of a display area of a display device according to an embodiment;

FIG. 11 is a plan view of first to third subpixel circuit regions of first to third subpixels, respectively, included in a pixel arranged in a first region of a display device according to an embodiment;

FIG. 12 is a plan view of first to third subpixel circuit regions of first to third subpixels, respectively, included in a pixel arranged in a second region of a display device according to an embodiment;

FIG. 13 is a schematic cross-sectional view of the display device, taken along line II-II′ of FIG. 11;

FIG. 14 is a schematic cross-sectional view of the display device, taken along line III-III′ of FIG. 12; and

FIGS. 15 to 19 are plan views illustrating components of each layer constituting the first to third subpixels in the second region of the display device shown in FIG. 12, according to the stacking order.

### DETAILED DESCRIPTION

One or more embodiments may be modified in various ways and may have various embodiments, and thus, specific embodiments are illustrated in the drawings and described in detail in the detailed description. Effects and features of one or more embodiments and methods for achieving the same could become clear by referring to embodiments described in detail below along with the drawings. However, one or more embodiments are not limited to the embodiments described below and may be implemented in various forms.

Hereinbelow, one or more embodiments are described in detail with reference to the accompanying drawings. When describing with reference to the drawings, identical or corresponding elements are assigned the same reference characters, and redundant descriptions thereof are omitted.

Herein, terms such as “first” and “second”, “first-1”, “first-2”, etc. are used not in a limiting sense but for the purpose of distinguishing one element from another element.

Herein, singular expressions include plural expressions, unless the context clearly dictates otherwise.

In the following embodiments, terms such as “comprise,” “include,” or “have” mean that a feature or component described in the specification is present, and do not exclude the possibility that one or more other features or components may be added.

Herein, when a part of a film, area, element, or the like is disposed over or on another part, it refers not only to a case where the part is directly on top of the other part, but also a case where another film, area, element, or the like is located therebetween.

In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

In cases where an embodiment may be implemented differently, a specific process sequence may be performed differently from the described sequence. For example, two processes described in succession may be performed substantially at the same time, or may be performed in an order opposite to that in which they are described.

Herein, “A and/or B” indicates A, B, or A and B. In addition, “at least one of A or B” indicates A, B, or A and B.

Herein, when films, areas, elements, or the like are described to be connected, it includes a case where the films, the areas, the elements, or the like are directly connected, or/and a case where the films, the areas, the elements, or the like are indirectly connected with other films, areas, or elements therebetween. For example, herein, when it is described that films, areas, elements, or the like are electrically connected, it indicates a case where the films, areas, elements, or the like are directly electrically connected, or/and a case where the films, areas, the elements, or the like are indirectly electrically connected with other films, areas, or elements therebetween.

An x-axis, a y-axis, and a z-axis are not limited to the three axes in the Cartesian coordinate system, but may be interpreted in a broad sense including the same. For example, the x-axis, the y-axis, and the z-axis may be perpendicular to one another, or may represent different directions that are not perpendicular to one another.

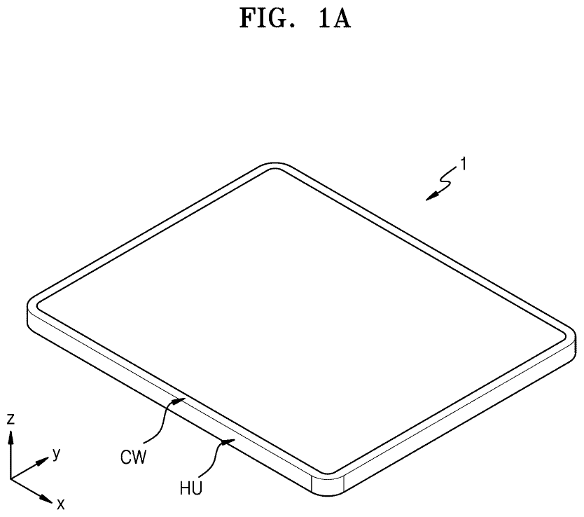

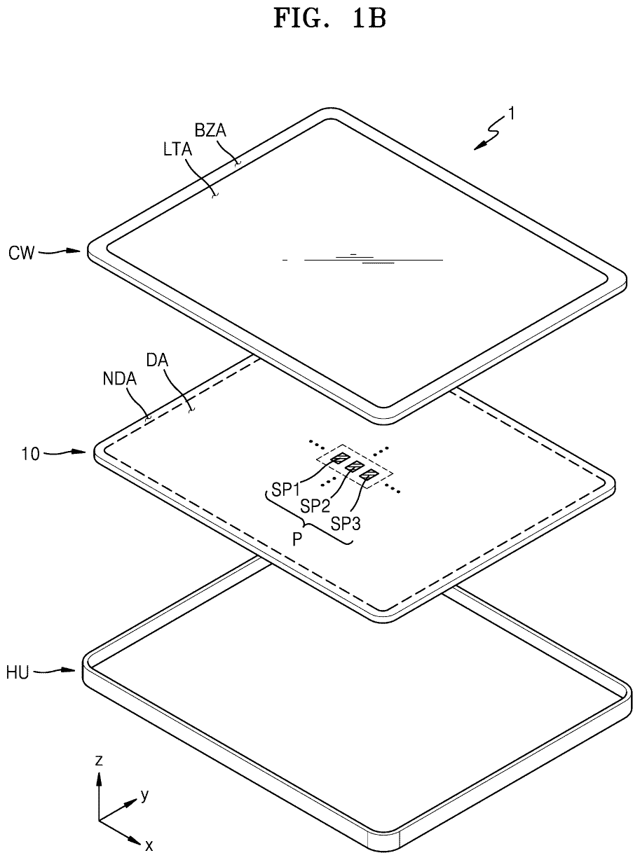

FIG. 1A is a schematic perspective view of an electronic device 1 according to an embodiment. FIG. 1B is an exploded perspective view of the electronic device 1 according to an embodiment.

In an embodiment, the electronic device 1 may display videos or still images and may include not only a portable electronic device such as a mobile phone, a smart phone, a tablet personal computer PC, a mobile communication terminal, an electronic organizer, an electronic book, a portable multimedia player (PMP), a navigation device, and an ultra-mobile personal computer (UMPC), but also a display screen of various products such as televisions, laptops, monitors, billboards, and Internet of Things (IoT) devices. In an embodiment, the electronic device 1 may include a wearable device such as a smart watch, watch phone, glasses-type display, or head mounted display (HMD). In an embodiment, the electronic device 1 may include a dashboard of a vehicle, a CID (Center Information Display) positioned on a center fascia or dashboard of a vehicle, a room mirror display replacing a side mirror of a vehicle, a rear-seat entertainment display (or a display positioned on a rear side of a front seat of a vehicle), a Head Up Display (HUD) installed at a front of a vehicle or projected on a front window glass, or a Computer Generated Hologram Augmented Reality Head Up Display (CGH AR HUD).

For example, the electronic device 1 may be one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, an in-vehicle display, a video wall including multiple displays tiled together, a theater or stadium screen, a light therapy device, and a signage.

Referring to FIGS. 1A and 1B, the electronic device 1 may display an image in a third direction (e.g., z direction) perpendicular to a first direction (e.g., x direction) and a second direction (e.g., y direction). The image may include not only moving images but also still images.

The electronic device 1 may detect a user input received from the outside. The user input may include various types of external inputs applied using a portion of the user's body, light, heat, pressure, or the like. The user input may be provided in various ways. The electronic device 1 may detect the user input applied to a side surface or rear surface of the electronic device 1 depending on a structure of the electronic device 1.

The electronic device 1 may include a cover window CW, a housing HU, and a display device 10. In an embodiment, the cover window CW may be combined with the housing HU to form the exterior of the electronic device 1.

The cover window CW may include a light-transmitting area LTA and a bezel area BZA. The light-transmitting area LTA may be an optically transparent area. For example, the light-transmitting area LTA may be an area with visible light transmittance of about 90% or more.

The bezel area BZA may define the shape of the light-transmitting area LTA. The bezel area BZA may be adjacent to the light-transmitting area LTA and may surround the light-transmitting area LTA. The bezel area BZA may be an area with relatively low light transmittance compared to the light-transmitting area LTA. The bezel area BZA may include an opaque material that blocks light. The bezel area BZA may have a certain color. The bezel area BZA may be defined by a bezel layer provided separately from the transparent substrate defining the light-transmitting area LTA, or may be defined by an ink layer formed by inserting or coloring the transparent substrate.

The housing HU may be combined with the cover window CW. The housing HU may accommodate the display device 10. The housing HU may include a rear surface and a side surface. The cover window CW may be located on a front of the housing HU. In other words, the cover window CW may be disposed above the housing HU. The housing HU may be combined with the cover window CW to provide an accommodation space. The display device 10 may be accommodated in the accommodation space provided between the housing HU and the cover window CW.

The housing HU may include a material having relatively high rigidity. For example, the housing HU may include glass, plastic, or metal, or include a plurality of frames and/or plates including a combination thereof. The housing HU may reliably protect the elements of the electronic device 1 housed in the internal space from external impact.

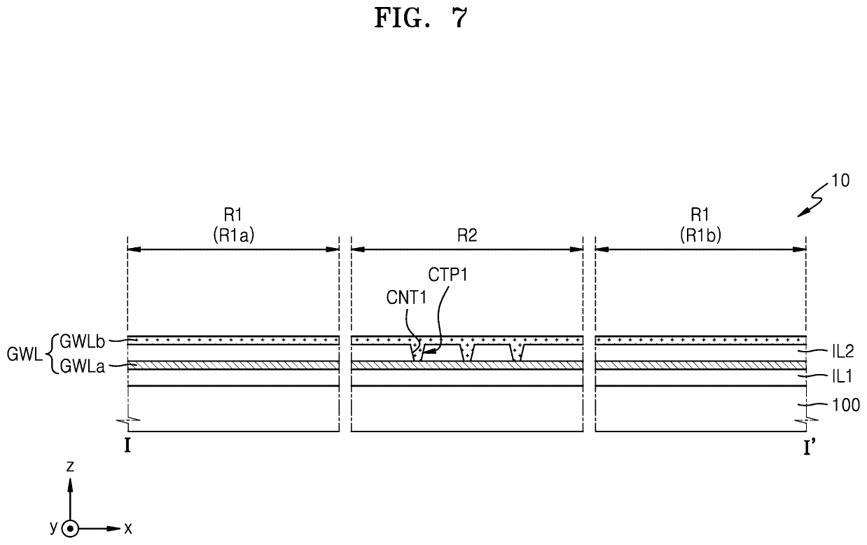

The display device 10 may display the image. The display device 10 may include a display area DA and a non-display area NDA. Because the display device 10 includes a substrate 100 (see FIG. 7), the substrate 100 includes a display area DA and a non-display area NDA.

The display area DA may be an active area that is activated by an electrical signal. In an embodiment, the display area DA may be an area where the image is displayed and at the same time an area where the user input is detected. The display area DA may be an area where a plurality of pixels P are arranged. The plurality of pixels P may be repeatedly arranged along the first direction (e.g., x direction) and the second direction (e.g., y direction). In an embodiment, a pixel P may include a first subpixel SP1, a second subpixel SP2, and a third subpixel SP3.

The display area DA may at least partially overlap the light-transmitting area LTA of the cover window CW. For example, part or all of the display area DA and the light-transmitting area LTA may overlap each other. Accordingly, the user may recognize the image or provide the user input through the light-transmitting area LTA. However, the disclosure is not limited thereto. For another example, an area where the image is displayed and an area where the user input is detected within the display area DA may be separate from each other.

The non-display area NDA may at least partially overlap the bezel area BZA of the cover window CW. The non-display area NDA may be an area covered by the bezel area BZA. The non-display area NDA may be adjacent to the display area DA. The non-display area NDA may be an area where the image IM is not displayed. A driving circuit or driving wiring for driving the display area DA may be located in the non-display area NDA.

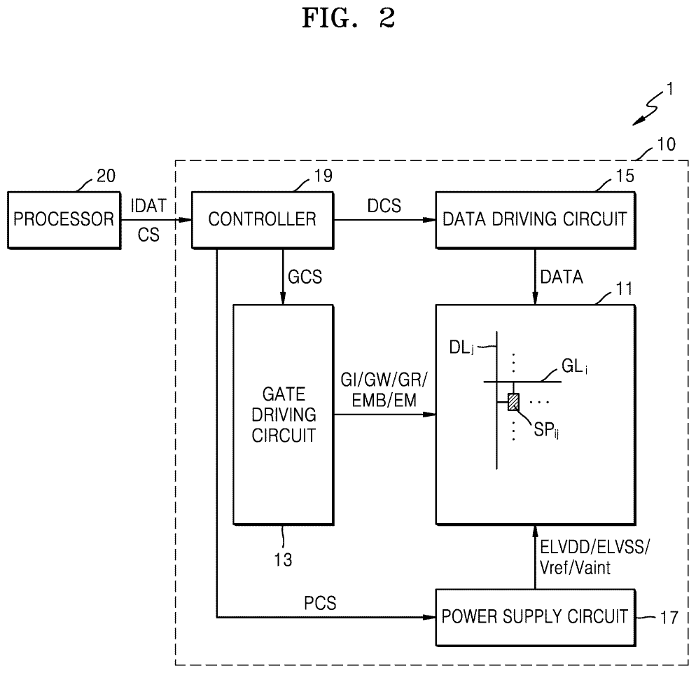

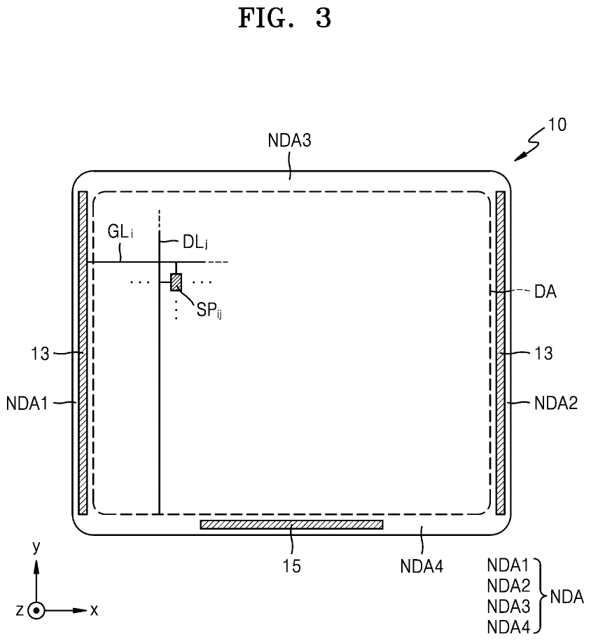

FIG. 2 is a schematic block diagram of the electronic device 1 according to an embodiment. FIG. 3 is a schematic plan view of a display device 10 according to an embodiment. As used herein, the “plan view” is a view in a thickness direction (i.e., z direction) of the display device 10.

Referring to FIG. 2, the electronic device 1 may include a display device 10 and a processor 20. The display device 10 may include a pixel portion 11, a gate driving circuit 13, a data driving circuit 15, a power supply circuit 17, and a controller 19.

The pixel portion 11 may include the plurality of pixels P (see FIG. 1B) arranged in the display area DA. Each of the subpixels (e.g., the first subpixel SP1 (see FIG. 1B), the second subpixel SP2 (see FIG. 1B), and the third subpixel SP3 (see FIG. 1B)) included in the pixel P (see FIG. 1B) may include a subpixel circuit, and a display element (e.g., a light-emitting diode) may be electrically connected to the subpixel circuit. Subpixels may display images in the display area DA (see FIG. 3) using light emitted from display elements corresponding to each subpixel. In an embodiment, each of the subpixels may emit red, green, or blue light. In an embodiment, each of the subpixels may emit red, green, blue or white light. FIG. 2 illustrates an embodiment of a subpixel SPij located in the i-th row (i is a natural number) and j-th column (j is a natural number) among multiple subpixels.

A subpixel circuit of each subpixel may be electrically connected to a gate line and the data line, and may include a plurality of transistors and at least one capacitor. FIG. 2 and FIG. 3 illustrate an embodiment in which a subpixel SPij located in the i-th row (i is a natural number) and the j-th column (j is a natural number) is connected to a gate line GLi located in the i-th row and a data line DLj located in the j-th column.

Various conductive lines that is configured to transmit electrical signals to be applied to the display area DA (see FIG. 3), peripheral circuits electrically connected to subpixel circuits, and pads to which printed circuit boards or driver IC chips are attached may be located in the non-display area NDA (see FIG. 3). For example, the non-display area NDA may be provided with the gate driving circuit 13, the data driving circuit 15, the power supply circuit 17, and the controller 19.

The gate driving circuit 13 is electrically connected to a plurality of gate lines and may receive a scan control signal GCS from the controller 19. The gate driving circuit 13 may generate a gate signal in response to the scan control signal GCS and sequentially supply it to the gate lines. The gate signal may be a gate control signal that controls turning on and off a transistor of a subpixel electrically connected to the gate line. The gate signal may be a square wave signal that includes an on voltage that may turn the transistor on and an off voltage that may turn the transistor off. According to an embodiment, the on voltage may be a high-level voltage (first level voltage) or a low-level voltage (second level voltage).

The gate driving circuit 13 may provide the gate signal to the subpixels located in the i-th row (i is a natural number) through the gate line GLi arranged in the i-th row (i is a natural number). For example, the gate driving circuit 13 may provide the gate signal to the subpixel SPij located in the i-th row (i is a natural number) and the j-th column (j is a natural number) through the gate line GLi arranged in the i-th row (i is a natural number). In other words, the gate line GLi may transmit gate signals to subpixels in the same row.

In FIGS. 2 and 3, one subpixel SPij is illustrated as being connected to one gate line GLi, but this is exemplary, and one subpixel SPij may be connected to two or more gate lines, and the gate driving circuit 13 may supply two or more gate signals having different timings for applying the on voltage to the corresponding gate lines. For example, one subpixel SPij may be electrically connected to the first to fifth gate lines, and the gate driving circuit 13 may apply a first gate signal GW, a second gate signal GR, a third gate signal EM, a fourth gate signal GI, and a fifth gate signal EMB to first gate lines, second gate lines, third gate lines, fourth gate lines, and fifth gate line, respectively.

The data driving circuit 15 may be connected to a plurality of data lines and may supply a data signal DATA to the data lines in response to a data control signal DCS from the controller 19. The data signal DATA supplied through the data line may be provided to the subpixel circuit of the subpixel. The data driving circuit 15 may convert input image data having grayscale input from the controller 19 into the data signal DATA in the form of voltage or current.

The data driving circuit 15 may provide the data signal DATA to subpixels located in the j-th column (j is a natural number) through the data line DLj arranged in the j-th column (j is a natural number). For example, the data driving circuit 15 may provide the data signal DATA to the subpixel SPij located in the i-th row (i is a natural number) and the j-th column (j is a natural number) through the data line DLj arranged in the j-th column (j is a natural number).

The power supply circuit 17 may generate voltages for driving the subpixels in response to a power control signal PCS from the controller 19. The power supply circuit 17 may generate a driving voltage ELVDD and a common voltage ELVSS and supply the driving voltage ELVDD and the common voltage ELVSS to the subpixels. The driving voltage ELVDD may be a high-level voltage provided to a first electrode (pixel electrode or anode) of the display element included in each subpixel. The common voltage ELVSS may be a low-level voltage provided to a second electrode (opposite electrode or cathode) of the display element included in each subpixel. The power supply circuit 17 may generate a reference voltage Vref and an initialization voltage Vaint and supply the reference voltage Vref and the initialization voltage Vaint to the subpixels.

A voltage level of the driving voltage ELVDD may be higher than a voltage level of the common voltage ELVSS. A voltage level of the reference voltage Vref may be lower than a voltage level of the driving voltage ELVDD. A voltage level of the initialization voltage Vaint may be equal to or higher than the voltage level of the common voltage ELVSS.

The controller 19 may configured to receive a control signal CS and input data IDAT from the processor 20 (e.g., an application processor AP, a graphic processing unit GPU, a central processing unit CPU, an image signal processor, a sensor hub processor, or a communication processor, etc.). In an embodiment, the control signal CS may include a vertical sync signal, a horizontal sync signal, an input data enable signal, or a master clock signal, but is not limited to. For another example, the controller 19 may output the scan control signal GCS, the data control signal DCS, and the power control signal PCS based on the control signal CS and input data IDAT transmitted from the processor 20. The scan control signal GCS, the data control signal DCS, and the power control signal PCS generated by the controller 19 may be transmitted to the gate driving circuit 13, data driving circuit 15, and power supply circuit 17, respectively. The scan control signal GCS output to the gate driving circuit 13 may include a plurality of clock signals and a gate start signal. The data control signal DCS output to the data driving circuit 15 may include a source start signal and clock signals.

Referring to FIG. 3, the display device 10 may include the display area DA and the non-display area NDA located outside the display area DA. The non-display area NDA may surround at least a portion of the display area DA.

In a plan view, the display area DA may have a rectangular shape. In an embodiment, the display area DA may have a polygonal shape (such as a triangle, pentagon, or hexagon), a circular shape, an oval shape, or an irregular shape, etc. A corner of an edge of the display area DA may be round. In an embodiment, the display device 10 may have the display area DA having a shape in which a length in the first direction (e.g., x direction) is longer than a length in a second direction (e.g., y direction), as illustrated in FIG. 3. In an embodiment, the display device 10 may have the display area DA having a shape in which a length in the second direction (e.g., the y direction) is longer than a length in the first direction (e.g., the x direction).

The non-display area NDA may include a first non-display area NDA1, a second non-display area NDA2, a third non-display area NDA3, and a fourth non-display area NDA4.

The gate driving circuit 13 may be located in each of the first non-display area NDA1 and the second non-display area NDA2, which are placed on opposite sides of the display area DA. For example, each of the first non-display area NDA1 and the second non-display area NDA2 may be located adjacent to the display area DA along the first direction (e.g., the x direction). The gate driving circuit 13 may include drivers for providing electrical signals to gate electrodes of each of the transistors electrically connected to the light-emitting diodes. Some of the subpixels arranged in the display area DA may be electrically connected to the gate driving circuit 13 arranged in the first non-display area NDA1, and the remaining subpixels may be connected to the gate driving circuit 13 arranged in the second non-display area NDA2. FIG. 3 illustrates that the gate driving circuit 13 is arranged in each of the first non-display area NDA1 and the second non-display area NDA2, but the present embodiment is not limited thereto. In another embodiment, the gate driving circuit 13 may be located in either the first non-display area NDA1 or the second non-display area NDA2.

The data driving circuit 15 may be located in the third non-display area NDA3 and/or the fourth non-display area NDA4, each of the third non-display area NDA3 and/or the fourth non-display area NDA4 connecting the first non-display area NDA1 and the second non-display area NDA2. For example, each of the third non-display area NDA3 and the fourth non-display area NDA4 may be located adjacent to the display area DA along the second direction (e.g., the y direction). In an embodiment, FIG. 3 illustrates that the data driving circuit 15 is located in the fourth non-display area NDA4. In an embodiment, the data driving circuit 15 may be located in each of the third non-display area NDA3 and the fourth non-display area NDA4.

FIG. 3 illustrates that the data driving circuit 15 is arranged in the fourth non-display area NDA4 of the display device 10, but the present embodiment is not limited thereto. In another embodiment, the display device 10 may further include a flexible circuit board electrically connected through a terminal portion arranged in the fourth non-display area NDA4, and the data driving circuit 15 may be arranged on the flexible circuit board.

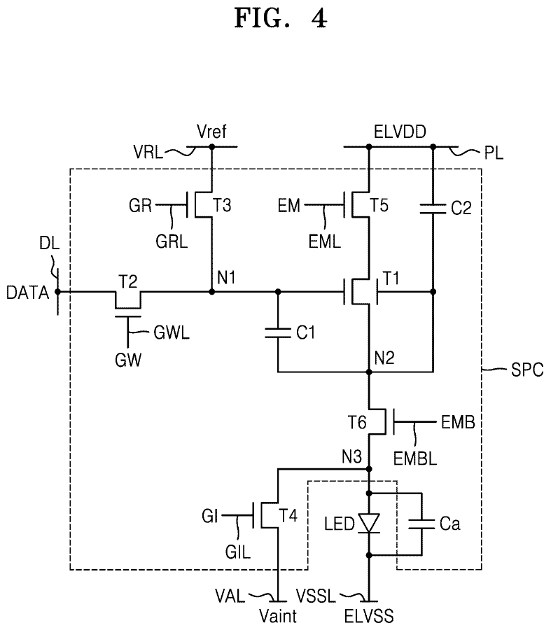

FIG. 4 is a schematic equivalent circuit diagram of a subpixel circuit SPC of a subpixel of a display device and a light-emitting diode LED electrically connected to the subpixel circuit SPC, according to an embodiment.

Referring to FIG. 4, the subpixel circuit SPC may be electrically connected to a first gate line GWL configured to transmit the first gate signal GW, a second gate line GRL configured to transmit the second gate signal GR, a third gate line EML configured to transmit the third gate signal EM, a fourth gate line GIL configured to transmit the fourth gate signal GI, a fifth gate line EMBL configured to transmit the fifth gate signal EMB, and a data line DL configured to transmit the data signal DATA. The first gate signal GW may be referred to as a write gate signal, and the first gate line GWL may be referred to as a write gate line. Because a light emission of the light-emitting diode LED is controlled by the third gate signal EM and the fifth gate signal EMB, the third gate signal EM and the fifth gate signal EMB may be referred to as light emission control signals, and the third gate line EML and the fifth gate line EMBL may be referred to as light emission control lines. The subpixel circuit SPC may be electrically connected to a driving voltage line PL configured to transmit the driving voltage ELVDD, a reference voltage line VRL configured to transmit the reference voltage Vref, and an initialization voltage line VAL configured to transmit the initialization voltage Vaint.

In an embodiment, each of the plurality of transistors included in the subpixel circuit SPC may be an n-channel MOSFET (NMOS) including an oxide semiconductor layer. However, this is exemplary, and the transistors of the present embodiment are not limited thereto. According to another embodiment, some of the plurality of transistors T1, T2, T3, T4, T5, T6, T7, and T8 may be p-channel metal oxide semiconductor field-effect transistors (p-channel MOSFETs) (PMOS) and the remaining ones may be n-channel metal oxide semiconductor field-effect transistors (n-channel MOSFETs) (NMOS). For example, among the plurality of transistors, a fifth transistor T5 and/or a sixth transistor T6 may be PMOS, and the remaining transistors may be NMOS. For example, the PMOS (e.g., the fifth transistor T5 and/or the sixth transistor T6) may include an inorganic semiconductor (e.g., amorphous silicon, poly silicon) or an organic semiconductor.

The subpixel circuit SPC may include first to sixth transistors T1 to T6, a first capacitor C1, a second capacitor C2, and an auxiliary capacitor Ca. A first transistor T1 may be a driving transistor that outputs a driving current corresponding to the data signal DATA, and second to sixth transistors T2 to T6 may be switching transistors configured to transmit signals. The first transistor T1 may be referred to as a driving transistor, a second transistor T2 may be referred to as a “data writing transistor”, a third transistor T3 may be referred to as a compensation transistor, a fourth transistor T4 may be referred to as an initialization transistor, a fifth transistor T5 may be referred to as an operation control transistor, and a sixth transistor T6 may be referred to as an emission control transistor.

A first terminal (or first electrode) and a second terminal (or second electrode) of each of the first to sixth transistors T1 to T6 may be a source (or source electrode) or a drain (or drain electrode) depending on voltages of the first terminal and the second terminal. For example, depending on the voltages of the first terminal and the second terminal, the first terminal may be a drain and the second terminal may be a source, or the first terminal may be a source and the second terminal may be a drain. Hereinafter, a node to which a first-1 gate electrode of the first transistor T1 is connected may be defined as a first node N1, and the node to which the second terminal of the first transistor T1 is connected may be defined as the second node N2.

The first transistor T1 may be connected to the driving voltage line PL and the light-emitting diode LED. The first transistor T1 may be connected between the fifth transistor T5 and the sixth transistor T6. The first transistor T1 may include a first gate electrode, a first terminal, and a second terminal connected to the second node N2. The first transistor T1 may include the first-1 gate electrode connected to the first node N1. The first transistor T1 may further include a first-2 gate electrode connected to the second terminal of the first transistor T1. The first-1 gate electrode and the first-2 gate electrode may be arranged facing each other in different layers. For example, the first-1 gate electrode and the first-2 gate electrode of the first transistor T1 may face each other, and a semiconductor layer may be disposed between the first-1 gate electrode and the first-2 gate electrode of the first transistor T1. In this specification, the first gate electrode of the first transistor T1 may refer to the first-1 gate electrode involved in turning on and off the first transistor T1.

The first-1 gate electrode of the first transistor T1 may be connected to a second terminal of the second transistor T2, a first terminal of the third transistor T3, and the first capacitor C1. The first-2 gate electrode of the first transistor T1 may be connected to a first terminal of the sixth transistor T6, the first capacitor C1, and the second capacitor C2. The first terminal of the first transistor T1 may be connected to the driving voltage line PL via the fifth transistor T5, and the second terminal of the first transistor T1 may be connected to a pixel electrode of the light-emitting diode LED via the sixth transistor T6. The first terminal of the first transistor T1 may be connected to a second terminal of the fifth transistor T5. The second terminal of the first transistor T1 may be connected to a first terminal of the sixth transistor T6, the first capacitor C1, and the second capacitor C2. The first transistor T1 may receive the 1 data signal DATA according to the switching operation of the second transistor T2 and control the amount of driving current flowing to the light-emitting diode LED.

The second transistor T2 may be connected to the data line DL and the first gate electrode of the first transistor T1. The second transistor T2 may include a second gate electrode connected to the first gate line GWL, a first terminal connected to the data line DL, and a second terminal connected to the first node N1. The second terminal of the second transistor T2 may be connected to the first gate electrode of the first transistor T1, the first terminal of the third transistor T3, and the first capacitor C1. The second transistor T2 may be turned on by the first gate signal GW transmitted to the first gate line GWL to electrically connect the data line DL and the first node N1, and may transmit the data signal DATA transmitted to the data line DL to the first node N1.

The third transistor T3 may be connected to the first gate electrode of the first transistor T1 and the reference voltage line VRL. The third transistor T3 may include a third gate electrode connected to the second gate line GRL, a first terminal connected to the first node N1, and a second terminal connected to the reference voltage line VRL. The first terminal of the third transistor T3 may be connected to the first gate electrode of the first transistor T1, the second terminal of the second transistor T2, and the first capacitor C1. The third transistor T3 may be turned on by the second gate signal GR transmitted to the second gate line GRL and may transmit the reference voltage Vref transmitted to the reference voltage line VRL to the first node N1.

The fourth transistor T4 may be connected to the sixth transistor T6 and the initialization voltage line VAL. The fourth transistor T4 may be connected between the light-emitting diode LED and the initialization voltage line VAL. The fourth transistor T4 may include a fourth gate electrode connected to the fourth gate line GIL, a first terminal connected to a third node N3, and a second terminal connected to the initialization voltage line VAL. The first terminal of the fourth transistor T4 may be connected to a second terminal of the sixth transistor T6 and the pixel electrode of the light-emitting diode LED. The fourth transistor T4 may be turned on by the fourth gate signal GI transmitted to the fourth gate line GIL and may transmit the initialization voltage Vaint transmitted to the initialization voltage line VAL to the third node N3 and initialize the pixel electrode (e.g., anode) of the light-emitting diode LED.

The fifth transistor T5 may be connected to the driving voltage line PL and the first transistor T1. The fifth transistor T5 may include a fifth gate electrode connected to the third gate line EML, a first terminal connected to the driving voltage line PL, and a second terminal connected to the first terminal of the first transistor T1. The fifth transistor T5 may be turned on or off depending on the third gate signal EM transmitted to the third gate line EML.

The sixth transistor T6 may be connected to the first transistor T1 and the light-emitting diode LED. The sixth transistor T6 may be connected between the second node N2 and the third node N3. The sixth transistor T6 may include a sixth gate electrode connected to the fifth gate line EMBL, the first terminal connected to the second node N2, and the second terminal connected to the third node N3. The first terminal of the sixth transistor T6 may be connected to the second terminal of the first transistor T1, the first capacitor C1, and the second capacitor C2. The second terminal of the sixth transistor T6 may be connected to the first terminal of the fourth transistor T4 and the pixel electrode of the light-emitting diode LED. The sixth transistor T6 may be turned on or off depending on the fifth gate signal EMB transmitted to the fifth gate line EMBL.

The first capacitor C1 may be connected between the first gate electrode of the first transistor T1 and the second terminal of the first transistor T1. A first electrode of the first capacitor C1 may be connected to the first node N1, and a second electrode of the first capacitor C1 may be connected to the second node N2. The first electrode of a first capacitor C1 may be connected to the first gate electrode of the first transistor T1, the second terminal of the second transistor T2, and the first terminal of the third transistor T3. The second electrode of the first capacitor C1 may be connected to the second terminal of the first transistor T1, the first-2 gate electrode of the first transistor T1, the second electrode of the second capacitor C2, and the first terminal of the sixth transistor T6. The first capacitor C1 may be a storage capacitor and may store the threshold voltage of the first transistor T1 and a voltage corresponding to the data signal DATA.

When the third transistor T3 and the fifth transistor T5 are turned on, the first transistor T1 may be turned on. When a voltage of the second terminal of the first transistor T1 drops to the difference (Vref−Vth1) between the reference voltage Vref and a threshold voltage (Vth1) of the first transistor T1, the first transistor T1 is turned off, and a voltage corresponding to the threshold voltage (Vth1) of the first transistor T1 is stored in the first capacitor C1, so that the threshold voltage (Vth1) of the first transistor T1 may be compensated.

The second capacitor C2 may be connected between the driving voltage line PL and the second node N2. The first electrode of the second capacitor C2 may be connected to the driving voltage line PL. The second electrode of the second capacitor C2 may be connected to the second terminal of the first transistor T1, the first-2 gate electrode of the first transistor T1, the second electrode of the first capacitor C1, and the first terminal of the sixth transistor T6.

A capacitance of each of the first capacitor C1 and the second capacitor C2 may vary depending on the color of light emitted from the light-emitting diode LED.

The auxiliary capacitor Ca may be electrically connected to the sixth transistor T6, the sustain voltage line VSSL, and the pixel electrode of the light-emitting diode LED. The auxiliary capacitor Ca stores and maintains a voltage corresponding to the voltage difference between the pixel electrode of the light-emitting diode LED and the sustain voltage line VSSL, thereby preventing or reducing the problem of black brightness increasing when the sixth transistor T6 is turned off.

The light-emitting diode LED may be connected to the first transistor T1 through the sixth transistor T6. The light-emitting diode LED may include the pixel electrode (anode) connected to the third node N3 and a opposite electrode (cathode) facing the pixel electrode, and the opposite electrode may be supplied with the common voltage ELVSS. In an embodiment, the opposite electrode (cathode) may be electrically connected to the sustain voltage line VSSL that extends into the display area DA (see, FIG. 3) and provides the common voltage ELVSS. A driving current output by the first transistor T1 flows through the light-emitting diode LED by the turned-on fifth transistor T5 and the turned-on sixth transistor T6, and the light-emitting diode LED may emit light with a brightness corresponding to the value of the driving current.

Although FIG. 4 illustrates that the subpixel circuit SPC includes six transistors, the present embodiment is not limited thereto. In another embodiment, the subpixel circuit SPC may include seven transistors. In an embodiment, the number of transistors in the subpixel circuit SPC may be 5 or less, or 8 or more.

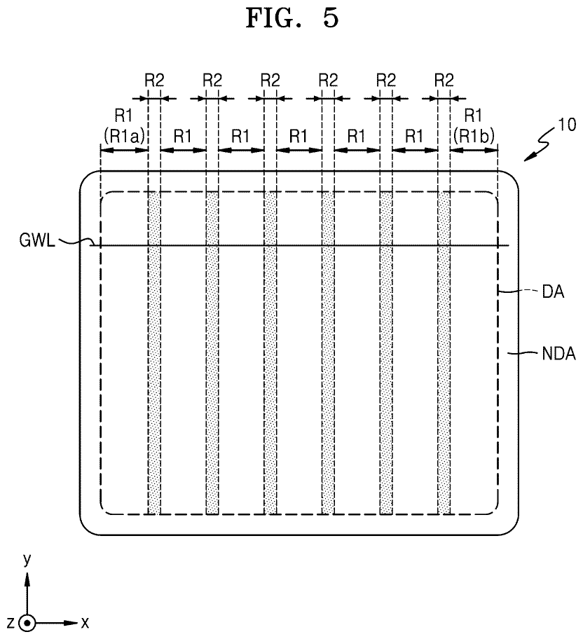

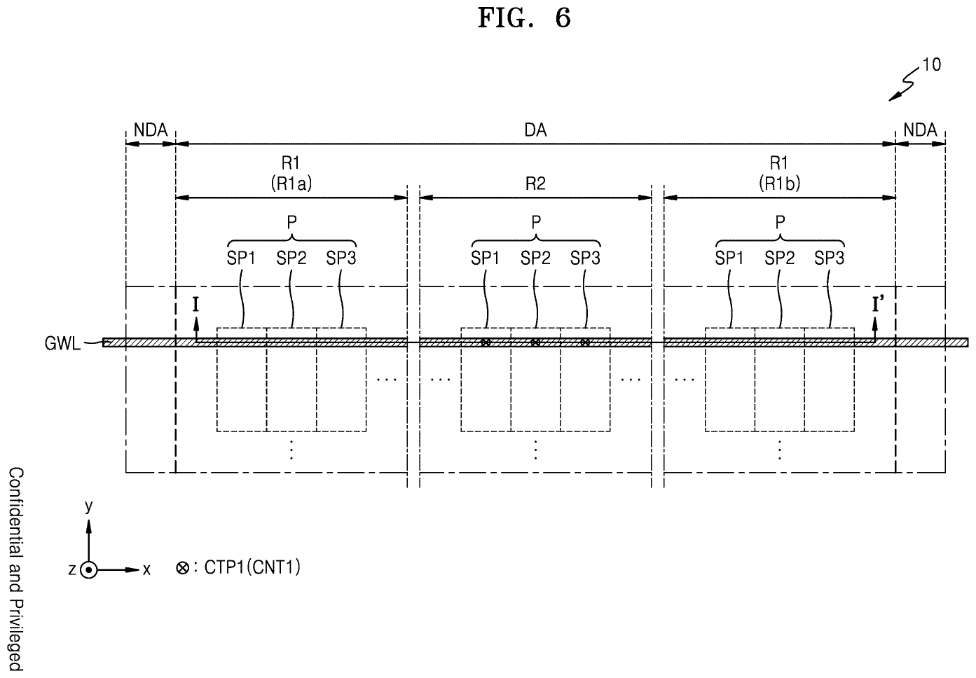

FIG. 5 is a schematic plan view of the display device 10 according to an embodiment. FIG. 6 is an enlarged plan view of a portion of the display device 10 according to an embodiment. FIG. 7 is a schematic cross-sectional view of the display device 10, taken along line I-I′ of FIG. 6.

FIG. 6 is an enlarged view of a portion of the display device 10 of FIG. 5, and illustrates, as an example, a first-1 region R1a and a first-2 region R1b located at opposite ends of a first region R1 in the display area DA, and a second region R2.

Referring to FIGS. 5 and 6, the display device 10 may include the display area DA and the non-display area NDA located outside the display area DA.

The display area DA may include first areas R1 and second areas R2. As illustrated in FIG. 6, at least one pixel P including subpixels (e.g., a first subpixel SP1, a second subpixel SP2, and a third subpixel SP3) may be arranged in each of the first regions R1 and the second regions R2. Because the display device 10 includes a substrate 100 (see FIG. 7), the substrate 100 (see FIG. 7) has the display area DA including first areas R1 and second areas R2.

Each of the second regions R2 may be spaced apart from the non-display area NDA in the first direction (e.g., in the x direction), and at least one of the first regions R1 may be located between the second regions R2 and the non-display area NDA. For example, some of the first regions R1 may be located adjacent to (or directly next to) the non-display area NDA. For example, each of the first-1 region R1a and the first-2 region R1b, which are arranged at opposite ends along the first direction (e.g., the x direction) among the first regions R1, respectively, may be located directly next to the non-display area NDA. For example, each of the first-1 region R1a and the first-2 region R1b may be located closer to the non-display area NDA than the second regions R2. In an embodiment, the first regions R1 and the second regions R2 may be arranged alternately along the first direction (e.g., the x direction). In an embodiment, as shown in FIG. 5, the second regions R2 may be spaced apart from each other at equal intervals along a first direction (e.g., the x direction). For example, the second regions R2 may be located at the 1/7, 2/7, 3/7, 4/7, 5/7, and 6/7 positions of the display area DA, respectively. However, the present embodiment is not limited thereto. In an embodiment, the second regions R2 may be spaced apart from each other at unequal intervals along the first direction (e.g., the x direction). In an embodiment, as shown in FIG. 5, six second regions R2 and seven first regions R1 are illustrated. However, the present embodiment is not limited thereto, and the numbers of the first regions R1 and second regions R2 may be variously modified.

In an embodiment, the number of pixels P arranged in each of the first regions R1 may be greater than the number of pixels P arranged in each of the second regions R2. For example, a width of one of the first regions R1 in the first direction (e.g., the x direction) may be greater than a width of one of the second regions R2 in the first direction. Although FIG. 5 illustrates that the width of each of the first regions R1 is greater than the width of each of the second regions R2, the present embodiment is not limited thereto. In another embodiment, the number of pixels P arranged in each of the first regions R1 may be less than the number of pixels P arranged in the second regions R2, and the width of each of the first regions R1 may be smaller than the width of each of the second regions R2.

Each of the first regions R1 may be defined as a region in which a first contact portion CTP1 (see FIG. 6) is not arranged. The first contact portion CTP1 (see FIG. 6) connects a first write gate line GWLa (see FIG. 7) and a second write gate line GWLb (see FIG. 7) of the first gate line GWL (hereinafter referred to as a write gate line) and will be described later with reference to FIG. 7. Each of the second regions R2 may be defined as a region in which the first contact portion CTP1 (see FIG. 6) is arranged.

The write gate line GWL may extend along the first direction (e.g., the x direction). The write gate line GWL may be electrically connected to the gate driving circuit 13 (see FIG. 2) and may transmit the first gate signal GW (see FIGS. 3 and 4, hereinafter referred to as a write gate signal) to pixels P arranged in the first regions R1 and pixels P arranged in the second regions R2.

Referring to FIGS. 6 and 7, the display device 10 may include a substrate 100 and the write gate line GWL disposed on the substrate 100. A first insulating structure IL1 may be disposed between the substrate 100 and the first write gate line GWLa. A second insulating structure IL2 may be disposed between the first write gate line GWLa and the second write gate line GWLb. Each of the first insulating structure IL1 and the second insulating structure IL2 may include one or more insulating layers.

The write gate line GWL may include the first write gate line GWLa and the second write gate line GWLb overlapping the first write gate line GWLa in a plan view. In an embodiment, the second write gate line GWLb may be disposed on the first write gate line GWLa. Each of the first write gate line GWLa and the second write gate line GWLb may extend along the first direction (e.g., the x direction). For example, each of the first write gate line GWLa and the second write gate line GWLb may extend through the first regions R1 and the second regions R2.

The display device 10 may include first contact portions CTP1 disposed between the first write gate line GWLa and the second write gate line GWLb and the first contact portions electrically connecting the first write gate line GWLa and the second write gate line GWLb. For example, the first contact portion CTP1 may be in contact with each of the first write gate line GWLa and the second write gate line GWLb. The first contact portions CTP1 may be located in first contact holes CNT1 defined as an area penetrating the second insulating structure IL2, respectively. As illustrated in FIGS. 6 and 7, the first contact portions CTP1 may be arranged only in the second regions R2 among the first and second regions R1 and R2 and spaced apart from each of the first regions R1. In other words, the first contact portions CTP1 may be arranged only in the second regions R2 and not in the first regions R1. In other words, the first contact portions CTP1 may overlap the second regions R2 and may not overlap the first regions R1 in a plan view.

In each of the second regions R2, the first contact portions CTP1 may be arranged corresponding to each of the subpixels (e.g., the first subpixel SP1, the second subpixel SP2, and the third subpixel SP3) of each pixel P arranged in the second regions R2. Accordingly, because the first contact portions CTP1 are arranged only in the second areas R2 excluding the first areas R1, the number of first contact portions CTP1 may be less than the number of subpixels arranged in the display area DA. For example, the number of first contact portions CTP1 arranged to correspond to subpixels arranged in the second regions R2 among the subpixels arranged along the same row may be less than the number of subpixels arranged along the same row.

In an embodiment, the first write gate line GWLa may be electrically connected to the gate driving circuit 13 (See FIG. 2), and the second write gate line GWLb may be electrically connected to the subpixels of each pixel P (e.g., the first subpixel SP1, the second subpixel SP2, and the third subpixel SP3). In an embodiment, an end of the first write gate line GWLa connected to the gate driving circuit (13, FIG. 2) may be arranged closer to the gate driving circuit (13, FIG. 2) than an end of the second write gate line GWLb. Accordingly, the write gate signal GW (see FIGS. 3 and 4) may be transmitted from the gate driving circuit (13, FIG. 2) to the first write gate line GWLa, the write gate signal GW (see FIGS. 3 and 4) is transmitted from the first write gate line GWLa to the second write gate line GWLb via the first contact portion CTP1, and the write gate signal GW (see FIGS. 3 and 4) may be transmitted from the second write gate line GWLb to the subpixels of each pixel P.

In the case of a comparative example in which the first contact portions CTP1 are arranged to correspond to all of the subpixels in the display area DA (even in the first regions), the waveform deviation between the write gate signals GW (see FIGS. 3 and 4) transmitted to the subpixels arranged in the edge area of the display area DA close to the gate driving circuit 13 (see FIG. 2) and the write gate signals GW transmitted to the subpixels arranged in the center area of the display area DA far from the gate driving circuit 13 (see FIG. 2) increases due to the difference in resistance of the write gate line GWL depending on locations, thereby deteriorating the quality of the display device 10.

Unlike the comparative example, in an embodiment, because the first contact portions CTP1 are not arranged in the first regions R1, and particularly, the first contact portions CTP1 are not arranged in the first-1 region R1a and the first-2 region R1b at opposite ends closest to the non-display area NDA, the resistance of the write gate line GWL in the edge area of the display area DA may be relatively increased, thereby reducing the difference in resistance with respect to the write gate line GWL in the center area of the display area DA. Accordingly, the embodiment may improve the quality of the display device 10 by reducing the waveform deviation between the write gate signal GW (see FIGS. 3 and 4) transmitted to the subpixels arranged in the edge area of the display area DA and the write gate signal GW transmitted to the subpixels arranged in the center area of the display area DA. In an embodiment, by alternately arranging first regions R1 where the first contact portion CTP1 is not arranged and second regions R2 where the first contact portion CTP1 is arranged, the resistance of the write gate line GWL may be relatively finely controlled to further reduce the difference in resistance between regions. Accordingly, the waveform difference of the write gate signal GW (See FIGS. 3 and 4) transmitted to subpixels arranged at different positions in the same row is effectively reduced, so the quality of the display device 10 may be improved.

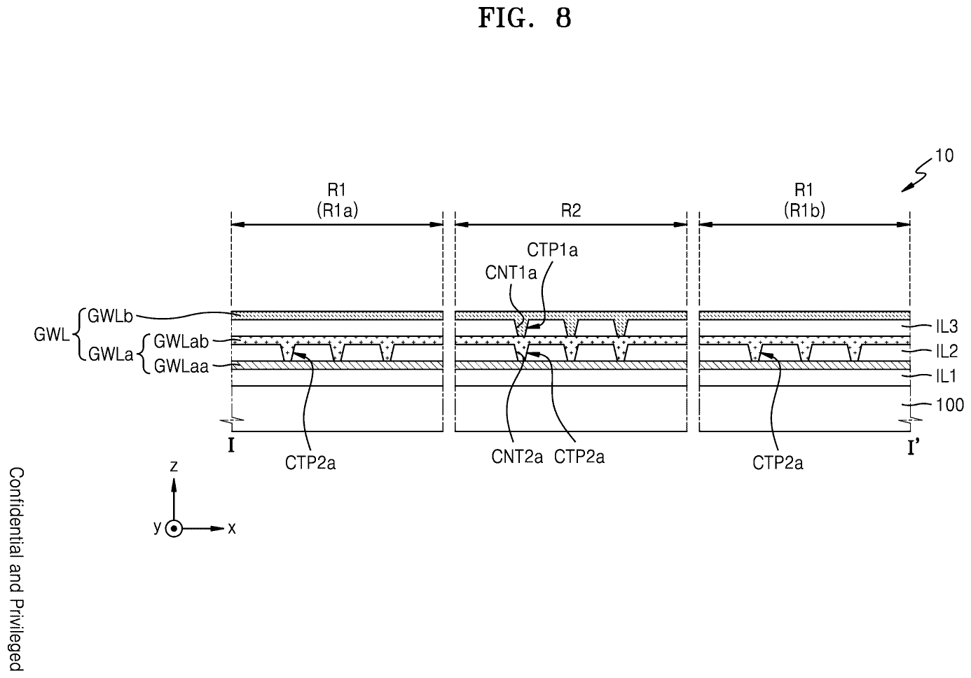

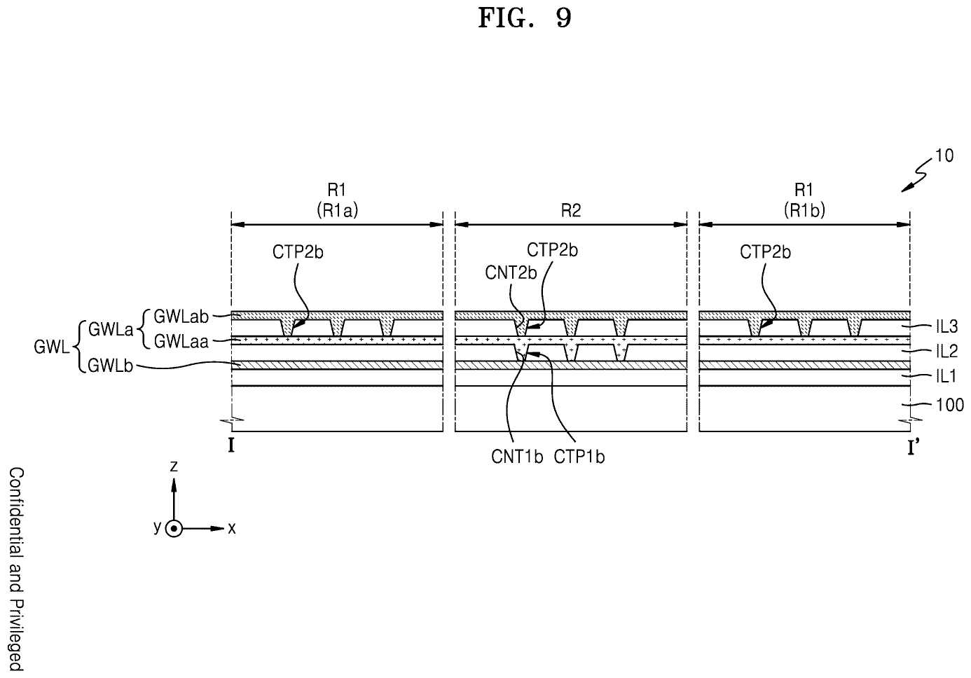

FIG. 8 is a schematic cross-sectional view of the display device 10, taken along line I-I′ of FIG. 6. FIG. 9 is a schematic cross-sectional view of the display device 10, taken along line I-I′ of FIG. 6. FIG. 8 is a modified embodiment of FIG. 7, therefore, redundant descriptions using identical or similar numeral reference to those in FIG. 7 will be omitted and the description will be focused on the differences.

Referring to FIG. 8, the write gate line GWL may include a plurality of write gate lines of three or more layers. For example, the write gate line GWL may include the first write gate line GWLa and the second write gate line GWLb, and the first write gate line GWLa may include a first lower write gate line GWLaa and a first upper write gate line GWLab. For example, the first upper write gate line GWLab may be disposed on the first lower write gate line GWLaa.

In an embodiment, the first write gate line GWLa may be disposed below the second write gate line GWLb. For example, the first upper write gate line GWLab may be disposed above the first lower write gate line GWLaa, and the second write gate line GWLb may be disposed above the first upper write gate line GWLab.

In an embodiment, the first insulating structure IL1 may be disposed between the substrate 100 and the first lower write gate line GWLaa. The second insulating structure IL2 may be disposed between the first lower write gate line GWLaa and the first upper write gate line GWLab. A third insulating structure IL3 may be disposed between the first upper write gate line GWLab and the second write gate line GWLb. Each of the first insulating structure IL1, the second insulating structure IL2, and the third insulating structure IL3 may include one or more insulating layers.

In an embodiment, the display device 10 may include second contact portions CTP2a disposed between the first lower write gate line GWLaa and the first upper write gate line GWLab and electrically connecting the first lower write gate line GWLaa and the first upper write gate line GWLab. For example, the second contact portion CTP2a may be in contact with each of the first lower write gate line GWLaa and the first upper write gate line GWLab. The second contact portions CTP2a may be located in second contact holes CNT2a defined as an area penetrating the second insulating structure IL2, respectively. As illustrated in FIG. 8, the second contact holes CNT2a may be located in each of the first regions R1 and the second regions R2. The second contact portions CTP2a may overlap both the first regions R1 and the second regions R2 in a plan view.

The first contact portions CTP1a may be arranged only in the second regions R2 excluding the first regions R1, and the second contact portions CTP2a may be arranged throughout the first region R1 and the second region R2, so that the number of second contact portions CTP2a may be greater than the number of first contact portions CTP1a. In an embodiment, the number of subpixels arranged in the display area DA and the number of second contact portions CTP2a may be the same. For example, the number of subpixels arranged along the same row and the number of second contact portions CTP2a arranged along the same row may be the same.

FIG. 9 is a modified embodiment of FIG. 7 and FIG. 8, and therefore, redundant descriptions using identical or similar numeral reference to those in FIG. 7 and FIG. 8 will be omitted and the description will be focused on the differences.

Referring to FIG. 9, the first write gate line GWLa may be disposed on the second write gate line GWLb. For example, the first lower write gate line GWLaa may be disposed above the second write gate line GWLb, and the first upper write gate line GWLab may be disposed above a first lower write gate line GWLaa.

In an embodiment, the first insulating structure IL1 may be disposed between the substrate 100 and the second write gate line GWLb. The second insulating structure IL2 may be disposed between the second write gate line GWLb and the first lower write gate line GWLaa. The third insulating structure IL3 may be disposed between the first lower write gate line GWLaa and the first upper write gate line GWLab.

Similar to the embodiment of FIG. 8, in the embodiment of FIG. 9, the display device 10 may include second contact portions CTP2b disposed between the first lower write gate line GWLaa and the first upper write gate line GWLab and electrically connecting the first lower write gate line GWLaa and the first upper write gate line GWLab. The second contact portions CTP2b may be located in the second contact holes CNT2b defined as an area penetrating the third insulating structure IL3, respectively. As illustrated in FIG. 9, the second contact holes CNT2b may be arranged throughout the first regions R1 and the second regions R2. The second contact portions CTP2b may overlap both the first regions R1 and the second regions R2 in a plan view.

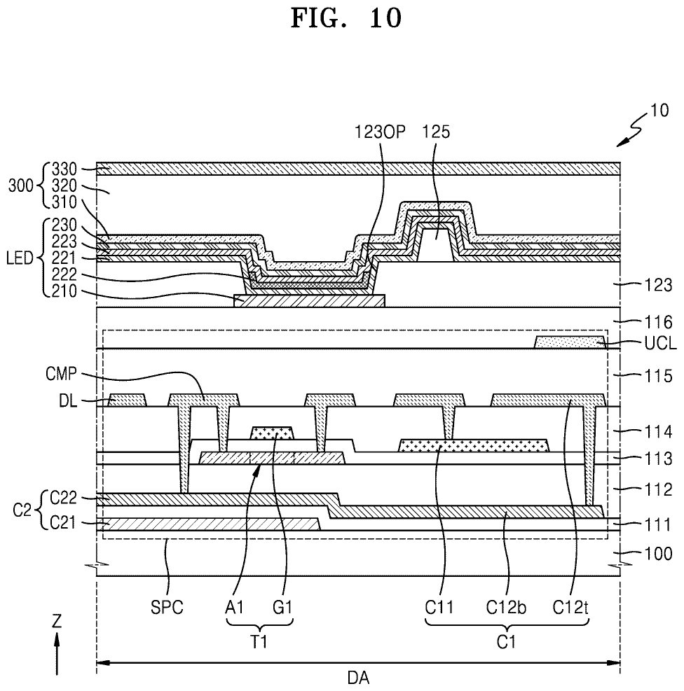

FIG. 10 is a cross-sectional view of a portion of the display area DA of the display device 10 according to an embodiment.

Referring to FIG. 10, the display device 10 may include the light-emitting diode LED arranged in the display area DA. A light-emitting diode LED may be disposed on a substrate 100, and the subpixel circuit SPC may be disposed between the substrate 100 and the light-emitting diode LED. In an embodiment, FIG. 10 illustrates some components of a subpixel circuit SPC, including the first transistor T1, the first capacitor C1, and the second capacitor C2.

The substrate 100 may include glass or a polymer resin. In an embodiment, the substrate 100 may have an alternating stacking structure of a base layer including a polymer resin and a barrier layer including an inorganic insulating material such as silicon oxide or silicon nitride. The polymer resin may include, for example, polyether sulfone, polyarylate, polyether imide, polyethylene naphthalate, polyethylene terephthalate, polyphenylene sulfide, polyimide, polycarbonate, cellulose triacetate, cellulose acetate propionate, or the like.

A first electrode C21 of the second capacitor C2 may be disposed on the substrate 100. The first electrode C21 of the second capacitor C2 may include a conductive material such as a metal, for example, molybdenum (Mo), aluminum (Al), copper (Cu), titanium (Ti), or the like, and may include a single-layer or multi-layer structure including the aforementioned materials.

A first insulating layer 111 may be disposed on the first electrode C21 of the second capacitor C2. The first insulating layer 111 may include an inorganic insulating material such as silicon oxide, silicon nitride, or silicon oxynitride, and may include a single-layer or multi-layer structure including the aforementioned inorganic insulating material.

A second lower electrode C12b of the first capacitor C1 and a second electrode C22 of the second capacitor C2 may be disposed on the first insulating layer 111. In an embodiment, the second lower electrode C12b of the first capacitor C1 and the second electrode C22 of the second capacitor C2 may be connected to each other and integrally provided. Each of the second lower electrode C12b of the first capacitor C1 and the second electrode C22 of the second capacitor C2 may include a conductive material such as a metal, for example, molybdenum (Mo), aluminum (Al), copper (Cu), titanium (Ti), or the like, and may include a single-layer or multi-layer structure including the aforementioned material.

A second insulating layer 112 may be disposed on the second electrode C22 of the second capacitor C2. The second insulating layer 112 may include an inorganic insulating material such as silicon oxide, silicon nitride, or silicon oxynitride, and may include a single-layer or multi-layer structure including the aforementioned inorganic insulating material. The second insulating layer 112 may be a buffer layer that prevents impurities from penetrating into a transistor, for example, the first transistor T1.

A semiconductor layer may be disposed on the second insulating layer 112. FIG. 10 illustrates that a first semiconductor layer A1 of the first transistor T1 is disposed on the second insulating layer 112. The first semiconductor layer A1 may include a channel region and a source region and a drain region arranged on opposite sides of the channel region. The first semiconductor layer A1 may include an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the first semiconductor layer A1 may be an InSnZnO (ITZO) semiconductor layer, an InGaZnO (IGZO) semiconductor layer, or the like. At least a portion of the first semiconductor layer A1 may undergo a conductive process (or metallization process) such as plasma treatment or the like.

A first gate electrode G1 may overlap a channel region of the first semiconductor layer A1 in a plan view, and the third insulating layer 113 may be disposed between the first gate electrode G1 and the first semiconductor layer A1. The second electrode C22 of the second capacitor C2 may face the first gate electrode G1 and the first semiconductor layer A1 may be disposed between the second electrode C22 of the second capacitor C2 and the first gate electrode G1. The second electrode C22 of the second capacitor C2 may be a lower gate electrode of the first transistor T1, and the first gate electrode G1 may be an upper gate electrode of the first transistor T1. The first gate electrode G1 may include a conductive material such as molybdenum (Mo), aluminum (Al), copper (Cu), titanium (Ti), or the like, and may be a multi-layer or single layer including the above conductive material. The third insulating layer 113 may include an inorganic insulating material such as silicon oxide, silicon nitride, or silicon oxynitride, and may include a single-layer or multi-layer structure including the aforementioned inorganic insulating material.

The first electrode C11 of the first capacitor C1 may overlap the second lower electrode C12b in a plan view, and each of the second insulating layer 112 and the third insulating layer 113 may be disposed between the first electrode C11 of the first capacitor C1 and the second lower electrode C12b. In FIG. 10, the first electrode C11 of the first capacitor C1 is illustrated as being separated from the first gate electrode G1, but this is not limited thereto, and the first electrode C11 of the first capacitor C1 may be connected to the first gate electrode G1 and integrally provided in another embodiment.

The first electrode C11 of the first capacitor C1 may include a conductive material such as molybdenum (Mo), aluminum (Al), copper (Cu), titanium (Ti), or the like, and may be a multi-layer or single layer including the above conductive material.

A fourth insulating layer 114 may be disposed on the first electrode C11 and the first gate electrode G1 of the first capacitor C1. The fourth insulating layer 114 may include an inorganic insulating material such as silicon oxide, silicon nitride, or silicon oxynitride, and may include a single-layer or multi-layer structure including the aforementioned inorganic insulating material.

The data line DL, a connection conductive pattern CMP, and a second upper electrode C12t of the first capacitor C1 may be disposed on the fourth insulating layer 114. The connection conductive pattern CMP may connect the first semiconductor layer A1 of the first transistor T1 and the second electrode C22 of the second capacitor C2. The second upper electrode C12t of the first capacitor C1 may overlap the second lower electrode C12b of the first capacitor C1 in a plan view, and each of the second insulating layer 112, the third insulating layer 113, and the fourth insulating layer 114 may be disposed between the second upper electrode C12t of the first capacitor C1 and the second lower electrode C12b of the first capacitor C1. The second upper electrode C12t of the first capacitor C1 may be connected to the second lower electrode C12b of the first capacitor C1 through a contact hole penetrating the second insulating layer 112, the third insulating layer 113, and the fourth insulating layer 114. The second upper electrode C12t of the first capacitor C1 may overlap the first electrode C11 of the first capacitor C1 in a plan view, and the fourth insulating layer 114 may be disposed between the second upper electrode C12t of the first capacitor C1 and the first electrode C11 of the first capacitor C1. Each of the data line DL, the connection conductive pattern CMP, and the second upper electrode C12t of the first capacitor C1 may include a conductive material including molybdenum (Mo), aluminum (Al), copper (Cu), titanium (Ti), or the like, and may include a single-layer or multi-layer structure including the aforementioned materials.

A fifth insulating layer 115 may be disposed on the data line DL, the connection conductive pattern CMP, and the second upper electrode C12t of the first capacitor C1, and may include an organic insulating material such as acrylic, Benzocyclobutene (BCB), polyimide, Hexamethyldisiloxane (HMDSO) or the like.

An upper conductive layer UCL may be disposed on the fifth insulating layer 115. An upper conductive pattern in the same layer as the upper conductive layer UCL may be connected to the light-emitting diode LED, and the upper conductive pattern may be connected to a transistor of the subpixel circuit SPC (e.g., a sixth transistor T6 (see FIG. 4)). Although not shown in FIG. 10, other voltage lines, such as the sustain voltage line (VSSL, FIG. 4), may be placed on the same layer as the upper conductive layer UCL, such as the fifth insulating layer 115. The upper conductive layer UCL may include a conductive material such as molybdenum (Mo), aluminum (Al), copper (Cu), titanium (Ti), or the like, and may be a multi-layer or single layer including the above conductive material.

A sixth insulating layer 116 may be disposed on the upper conductive layer UCL and may include an organic insulating material such as acrylic, Benzocyclobutene (BCB), polyimide, or Hexamethyldisiloxane (HMDSO).

The light-emitting diode LED may include a pixel electrode 210, an emission layer 222, and an opposite electrode 230.

The pixel electrode 210 may be disposed on the sixth insulating layer 116. The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a conductive oxide layer above and/or below the aforementioned reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 210 may have a three-layer structure of ITO layer/Ag layer/ITO layer.

A bank layer 123 may be disposed on the pixel electrode 210. An opening 123OP above the pixel electrode 210 may be provided with the bank layer 123 defined therethrough. The bank layer 123 may cover an edge of the pixel electrode 210. The bank layer 123 may include an organic insulating material. In an embodiment, the bank layer 123 may include a light-transmitting organic insulating material. In an embodiment, the bank layer 123 may include an organic insulating material including a light-shielding material. In an embodiment, the bank layer 123 may include a polyimide (PI)-based binder and a mixture of red, green, and blue pigments. In an embodiment, the bank layer 123 may include a mixture of a cardo-based binder resin and a lactam-based black pigment and a blue pigment. In an embodiment, the bank layer 123 may include carbon black. The bank layer 123 may improve the contrast of the display device 10.

The spacer 125 may be disposed on the bank layer 123. The spacer 125 may include a material different from a material of the bank layer 123. For example, the bank layer 123 may include a negative photosensitive material, the spacer 125 may include a positive photosensitive material, and the bank layer 123 and the spacer 125 may include different materials, with each being formed through a separate mask process. In an embodiment, the spacer 125 and the bank layer may include the same material and be formed together in the same mask process (e.g., a halftone mask process).

The emission layer 222 may include a high-molecular weight organic material or low-molecular weight organic material, which emit light of certain color. The emission layer 222 may include a material that emits red light, green light, or blue light depending on the light-emitting diode LED.

A functional layer may be further included below and/or above the emission layer 222. For example, a first functional layer 221 may be further included between the pixel electrode 210 and the emission layer 222, and a second functional layer 223 may be further included between the emission layer 222 and the opposite electrode 230 described later. The first functional layer 221 may include a hole transport layer and/or a hole injection layer. The second functional layer 223 may include an electron transport layer and/or an electron injection layer.

The opposite electrode 230 may include a conductive material with a low work function. For example, the opposite electrode 230 may include a transparent layer (or a semitransparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the opposite electrode 230 may further include a layer including ITO, IZO, ZnO, or In2O3 on the transparent layer (or the semitransparent layer) including the above-mentioned material.

Unlike the pixel electrodes 210, which are individually formed to correspond to each light-emitting diode LED, the opposite electrodes 230 may be extended to correspond to the pixel electrodes 210. For example, the pixel electrode 210 of one light-emitting diode LED and the pixel electrode 210 of another light-emitting diode LED may be separated and spaced from each other, but the opposite electrode 230 overlapping the pixel electrodes 210 in a plan view may be extended to cover the pixel electrodes 210 described above.

The encapsulation layer 300 may be disposed on the light-emitting diode LED and may include at least one inorganic encapsulation layer and at least one organic encapsulation layer. According to an embodiment, FIG. 10 illustrates that the encapsulation layer 300 includes the first inorganic encapsulation layer 310, the organic encapsulation layer 320, and the second inorganic encapsulation layer 330.

Each of the first inorganic encapsulation layer 310 and the second inorganic encapsulation layer 330 may include one or more inorganic insulating materials selected from the group consisting of aluminum oxide, titanium oxide, tantalum oxide, hafnium oxide, zinc oxide, silicon nitride, and silicon oxynitride. The first inorganic encapsulation layer 310 and second inorganic encapsulation layer 330 may each have a single layer or multilayer structure including the above inorganic insulating material. The organic encapsulation layer 320 may include a polymer-based material. The polymer-based material may include acrylic resin, epoxy resin, polyimide, polyethylene, or the like. In an embodiment, the organic encapsulation layer 320 may include acrylate.

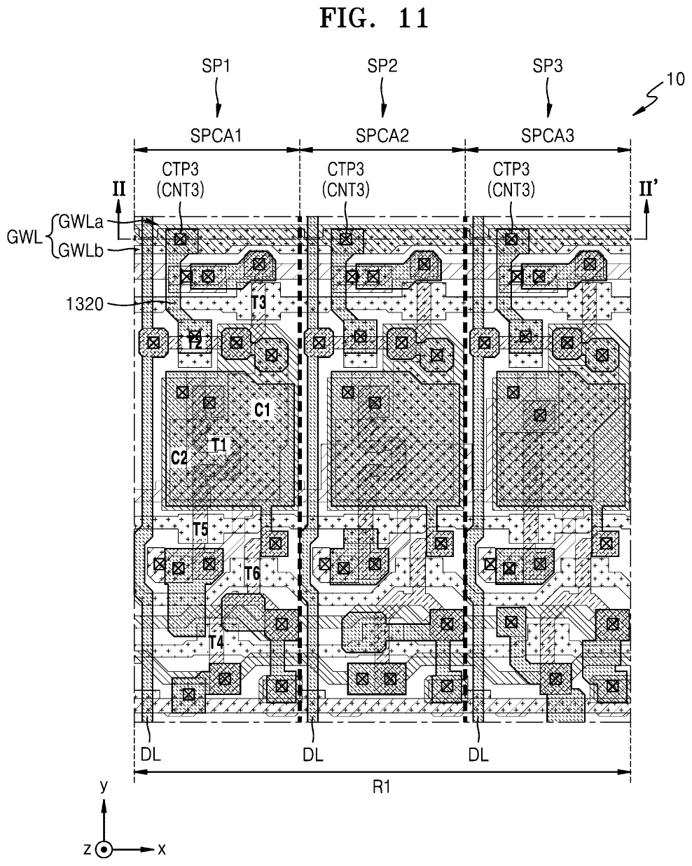

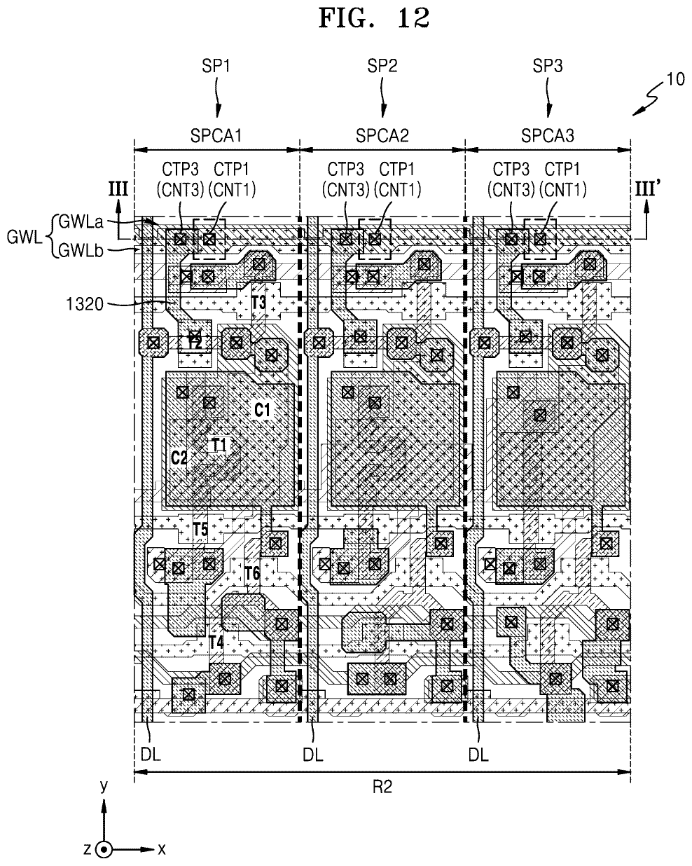

FIG. 11 is a plan view of first to third subpixel circuit regions SPCA1 to SPCA3 of first to third subpixels SP1 to SP3 included in the pixel P arranged in the first region R1 of the display device 10 according to an embodiment. FIG. 12 is a plan view of first to third subpixel circuit regions SPCA1 to SPCA3 of first to third subpixels SP1 to SP3 included in the pixel P arranged in the second region R2 of the display device 10 according to an embodiment.

Each of the first to third subpixel circuit regions SPCA1 to SPCA3 of FIG. 11 may be a planar structure in the first region R1 of the subpixel circuit SPC of the display device 10 described with reference to FIG. 4 and FIG. 10. Each of the first to third subpixel circuit regions SPCA1 to SPCA3 of FIG. 12 may be a planar structure in the second region R2 of the subpixel circuit SPC of the display device 10 described with reference to FIG. 4 and FIG. 10.

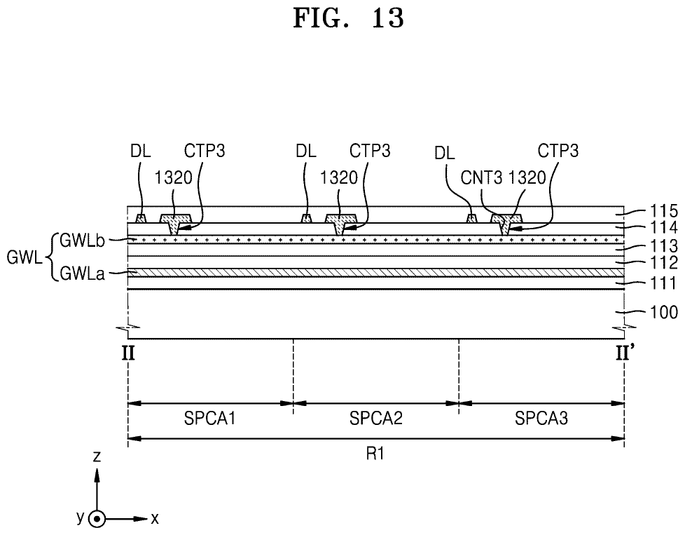

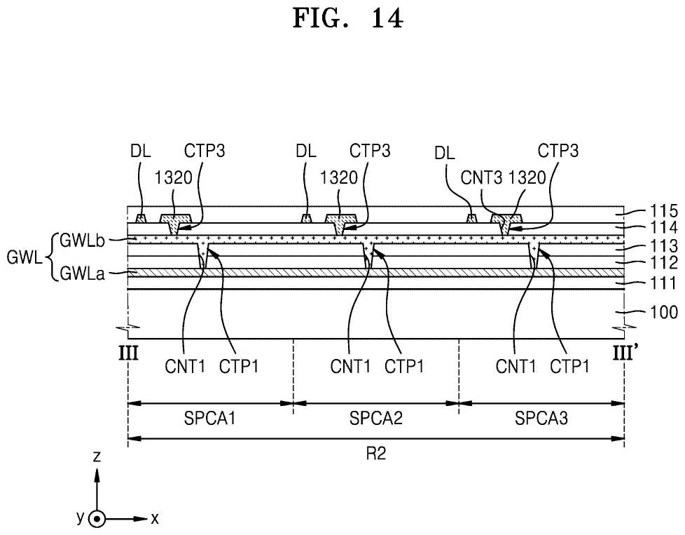

FIG. 13 is a schematic cross-sectional view of the display device 10, taken along line II-II′ of FIG. 11. FIG. 14 is a schematic cross-sectional view of the display device 10, taken along line III-III′ of FIG. 12.

Referring to FIGS. 11 to 14, a first subpixel circuit region SPCA1 in which the first subpixel circuit of the first subpixel SP1 is arranged, a second subpixel circuit region SPCA2 in which the second subpixel circuit of the second subpixel SP2 is arranged, and a third subpixel circuit region SPCA3 in which the third subpixel circuit of the third subpixel SP3 is arranged may be arranged adjacent to each other along the first direction (e.g., x direction). FIGS. 11 and 12 illustrate the first to sixth transistors T1 to T6, the first capacitor C1, and the second capacitor C2 of each of the first subpixel SP1, the second subpixel SP2, and the third subpixel SP3.

In an embodiment, the first transistor T1 and the first capacitor C1 may overlap each other in a plan view.

In an embodiment, in a plan view, the second transistor T2 and the third transistor T3 may be arranged on one side of the first transistor T1, and the fourth transistor T4, the fifth transistor T5, and the sixth transistor T6 may be arranged on the other side of the first transistor T1. For example, in a plan view, the second transistor T2 and the third transistor T3 may be placed on an upper side of the first transistor T1, and the fourth transistor T4, the fifth transistor T5, and the sixth transistor T6 may be placed on a lower side of the first transistor T1.

The write gate line GWL may extend in the first direction (e.g., the x direction) through the first subpixel circuit region SPCA1, the second subpixel circuit region SPCA2, and the third subpixel circuit region SPCA3. The write gate line GWL may include the first write gate line GWLa and the second write gate line GWLb that overlap each other, in a plan view. For example, each of the first write gate line GWLa and the second write gate line GWLb may extend in the first direction (e.g., the x direction) through the first subpixel circuit region SPCA1, the second subpixel circuit region SPCA2, and the third subpixel circuit region SPCA3.

In an embodiment, the first write gate line GWLa may be disposed on the first insulating layer 111. The first insulating layer 111 may correspond to the first insulating structure IL1 described with reference to FIG. 7. The second insulating layer 112 may be disposed on the first write gate line GWLa, and the third insulating layer 113 may be disposed on the second insulating layer 112. The second insulating layer 112 and the third insulating layer 113 may correspond to the second insulating structure IL2 described with reference to FIG. 7. The second write gate line GWLb may be disposed on the third insulating layer 113. The fourth insulating layer 114 may be disposed on the second write gate line GWLb, and the data line DL and a second connection pattern 1320 may be disposed on the fourth insulating layer 114. The fifth insulating layer 115 may be disposed on the data line DL and the second connection pattern 1320.

In each of the first region R1 and the second region R2, the second write gate line GWLb may be connected to the second connection pattern 1320, and the second connection pattern 1320 may be electrically connected to the second transistor T2 (e.g., the second gate electrode of the second transistor T2), so that the second write gate line GWLb may be electrically connected to the second transistor T2 (e.g., the second gate electrode of the second transistor T2). The second write gate line GWLb may be connected to the second connection pattern 1320 by a third contact portion CTNP3 located in a third contact hole CNT3 penetrating at least one insulating layer disposed between the second write gate line GWLb and the second connection pattern 1320. Because the data line DL and the second transistors T2 (e.g., a semiconductor layer of the second transistor T2) corresponding to the first subpixel circuit region SPCA1, the second subpixel circuit region SPCA2, and the third subpixel circuit region SPCA3, are connected, the data signal DATA (see FIG. 2) may be transmitted to each of the second transistors T2.

Referring to FIG. 11 and FIG. 13, in the first region R1, the first write gate line GWLa and the second write gate line GWLb may be spaced apart from each other with the second insulating layer 112 and the third insulating layer 113 disposed between the first write gate line GWLa and the second write gate line GWLb. In the first region R1, the first write gate line GWLa and the second write gate line GWLb may be spaced apart from each other in the third direction (e.g., the z direction) and may not be connected. For example, in each of the first subpixel circuit region SPCA1, the second subpixel circuit region SPCA2, and the third subpixel circuit region SPCA3 of the first region R1, the first write gate line GWLa and the second write gate line GWLb may be spaced apart from each other and not connected. In other words, unlike the second region R2 described with reference to FIGS. 12 and 14, the first contact portion CTP1 connecting the first write gate line GWLa and the second write gate line GWLb may not be arranged in the first region R1.

Referring to FIG. 12 and FIG. 14, in the second region R2, the first write gate line GWLa and the second write gate line GWLb may be connected through the first contact portion CTP1 located in the first contact hole CNT1 penetrating the second insulating layer 112 and the third insulating layer 113. For example, in each of the first subpixel circuit region SPCA1, the second subpixel circuit region SPCA2, and the third subpixel circuit region SPCA3 of the second region R2, the first write gate line GWLa and the second write gate line GWLb may be connected through the first contact portion CTP1. In other words, the first contact portion CTP1 connecting the first write gate line GWLa and the second write gate line GWLb may be arranged in the second regions R2. The first contact portions CTP1 may be arranged to correspond to each of the first subpixel circuit region SPCA1, the second subpixel circuit region SPCA2, and the third subpixel circuit region SPCA3. In an embodiment, as illustrated in FIG. 12, the first contact portion CTP1 and the third contact portion CTP3 may be arranged along the first direction (e.g., the x direction) in a plan view.

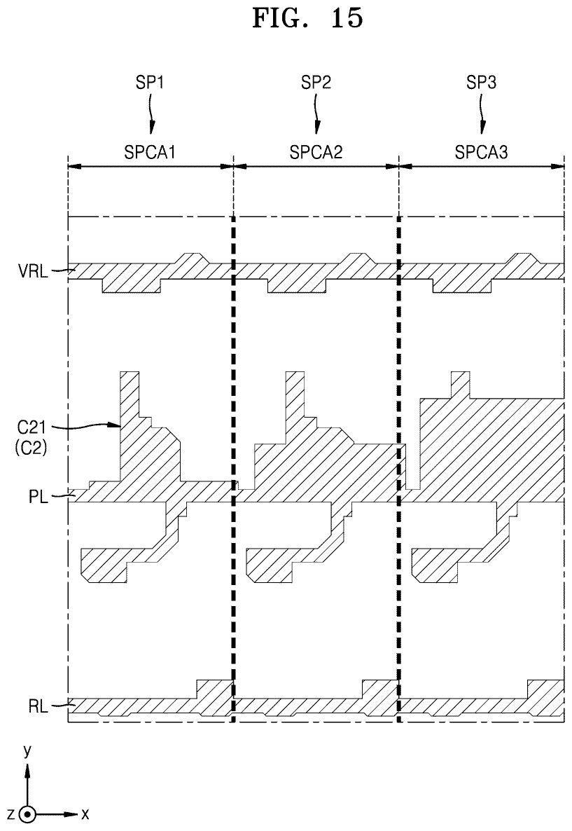

FIGS. 15 to 19 are plan views illustrating the components of each layer constituting the first to third subpixels SPC1 to SPC3 in the second region R2 of the display device 10 shown in FIG. 12, according to the stacking order. The first region R1 of FIG. 11 and the second region R2 of FIG. 12 differ in the presence or absence of the first contact portion CTP1 connecting different layers of the write gate line GWL, and the arrangement of other components is the same or similar. Therefore, for convenience of explanation, the description will focus on the first subpixel circuit region SPCA1, the second subpixel circuit region SPCA2, and the third subpixel circuit region SPCA3 in the second region R2 of FIG. 12.

Referring to FIG. 15, the driving voltage line PL, the reference voltage line VRL, and a repair line RL may be disposed on a substrate 100 (see FIG. 10).

Each of the driving voltage line PL, the reference voltage line VRL, and the repair line RL may extend in the first direction (e.g., the x direction) through the first subpixel circuit region SPCA1, the second subpixel circuit region SPCA2, and the third subpixel circuit region SPCA3.

The driving voltage line PL may include the first electrode C21 of the second capacitor C2. For example, the driving voltage line PL may include the first electrode C21 of the second capacitor C2 of each of the first to third subpixels (SP1, SP2, SP3), and the first electrodes C21 of the second capacitors C2 of each of the first to third subpixels (SP1, SP2, SP3) may be connected to each other integrally.

The repair line RL may be a spare line that may be used when a defect occurs in a signal line or voltage line included in the subpixel circuits of the first to third subpixels SP1 to SP3.

The driving voltage line PL, the reference voltage line VRL, and the repair line RL may include the same material. Each of the driving voltage line PL, the reference voltage line VRL, and the repair line RL may include a conductive material including molybdenum (Mo), aluminum (Al), copper (Cu), titanium (Ti), or the like, and may include a single-layer or multi-layer structure including the aforementioned materials.

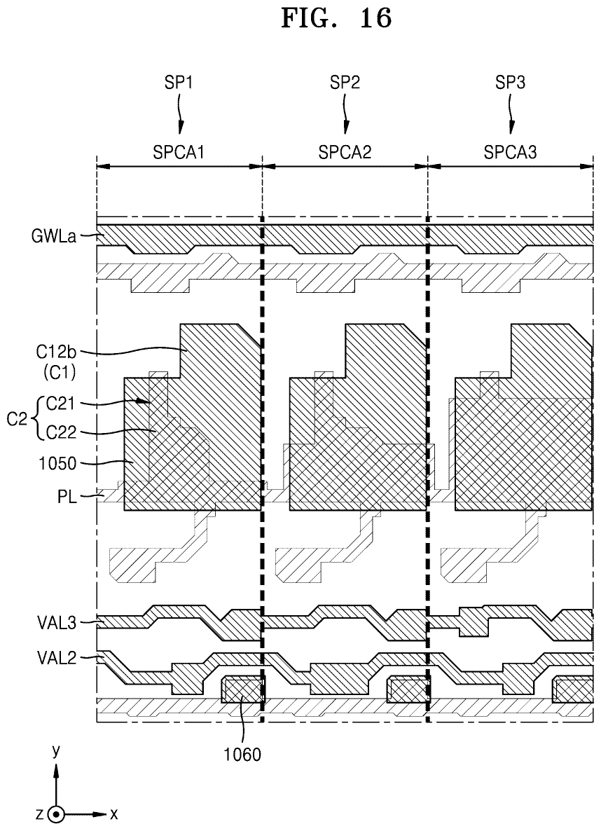

Referring to FIGS. 15 and 16, the first insulating layer 111 (see FIG. 10) may be disposed on the driving voltage line PL, the reference voltage line VRL, and the repair line RL, and a first conductive pattern 1050, the first write gate line GWLa, a second initialization voltage line VAL2, and a third initialization voltage line VAL3 may be disposed on the first insulating layer 111 (see FIG. 10).

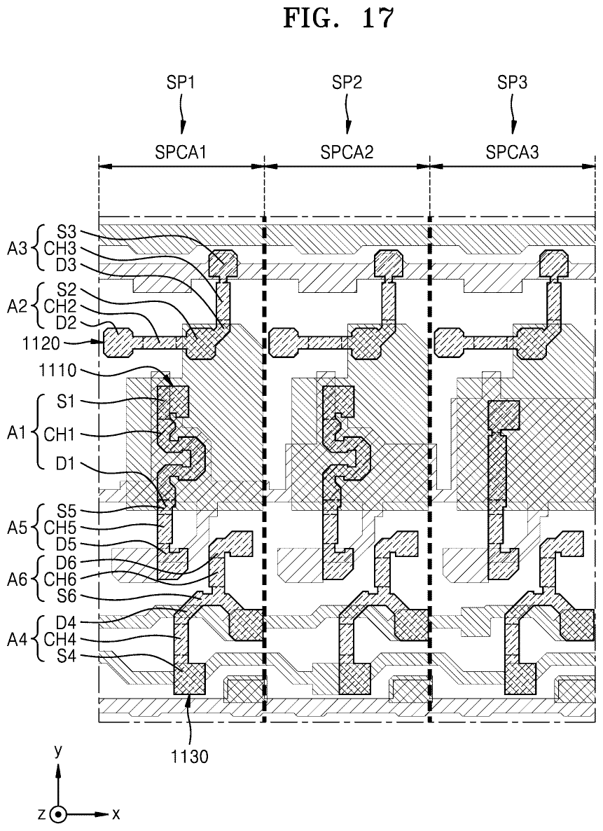

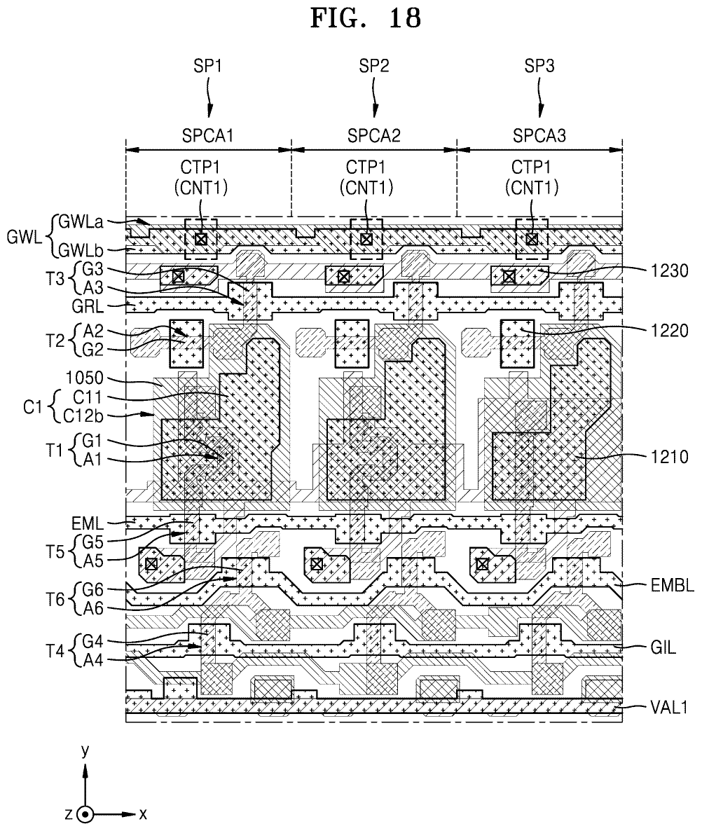

The first conductive pattern 1050 may be an isolated shape. The first conductive pattern 1050 may be arranged corresponding to each of the first subpixel circuit region SPCA1, the second subpixel circuit region SPCA2, and the third subpixel circuit region SPCA3. The first conductive pattern 1050 may include the second electrode C22 of the second capacitor C2 overlapping the first electrode C21 of the second capacitor C2 in a plan view. The first conductive pattern 1050 may include the second lower electrode C12b of the first capacitor C1. In an embodiment, the first conductive pattern 1050 may include a lower gate electrode (e.g., a first-2 gate electrode) of the first transistor T1 (see FIG. 18) overlapping the first semiconductor layer A1 (see FIGS. 17 and 18) of the first transistor T1 (see FIG. 18) in a plan view. The second electrode C22 of the second capacitor C2 and the second lower electrode C12b of the first capacitor C1 may be provided integrally and may be connected to the second node N2 described with reference to FIG. 4.

Each of the first write gate line GWLa, the second initialization voltage line VAL2, and the third initialization voltage line VAL3 may extend in the first direction (e.g., the x direction) through the first subpixel circuit region SPCA1, the second subpixel circuit region SPCA2, and the third subpixel circuit region SPCA3.

The first write gate line GWLa may be arranged on one side of the first conductive pattern 1050, and each of the second initialization voltage line VAL2 and the third initialization voltage line VAL3 may be arranged on the other side of the first conductive pattern 1050. For example, in a plan view, the first write gate line GWLa may be arranged on an upper side of the first conductive pattern 1050, and each of the second initialization voltage line VAL2 and the third initialization voltage line VAL3 may be arranged on a lower side of the first conductive pattern 1050. For example, in a plan view, the first conductive pattern 1050 may be located between the first write gate line GWLa and the second initialization voltage line VAL2.

The first conductive pattern 1050, the first write gate line GWLa, the second initialization voltage line VAL2, and the third initialization voltage line VAL3 may include the same material. Each of the first conductive pattern 1050, the first write gate line GWLa, the second initialization voltage line VAL2, and the third initialization voltage line VAL3 may include a conductive material including molybdenum (Mo), aluminum (Al), copper (Cu), titanium (Ti), or the like, and may include a single-layer or multi-layer structure including the aforementioned materials.

Referring to FIGS. 16 and 17, the second insulating layer 112 (see FIG. 10) may be disposed on the first conductive pattern 1050, the first write gate line GWLa, the second initialization voltage line VAL2, and the third initialization voltage line VAL3, and a semiconductor layer including first to third semiconductor patterns 1110, 1120, and 1130 may be disposed on the second insulating layer 112 (see FIG. 10).

Each of a first semiconductor pattern 1110, a second semiconductor pattern 1120, and a third semiconductor pattern 1130 may be an isolated shape. For example, the first semiconductor pattern 1110, the second semiconductor pattern 1120, and the third semiconductor pattern 1130 may be spaced apart from each other. Each of the first semiconductor pattern 1110, the second semiconductor pattern 1120, and the third semiconductor pattern 1130 may be arranged to correspond to each of the first subpixel circuit region SPCA1, the second subpixel circuit region SPCA2, and the third subpixel circuit region SPCA3.

The first semiconductor pattern 1110 may include the first semiconductor layer A1 and a fifth semiconductor layer A5. In other words, the first semiconductor layer A1 and the fifth semiconductor layer A5 may be connected integrally. The second semiconductor pattern 1120 may include a second semiconductor layer A2 and a third semiconductor layer A3. In other words, the second semiconductor layer A2 and the third semiconductor layer A3 may be connected integrally. The third semiconductor pattern 1130 may include a fourth semiconductor layer A4 and a sixth semiconductor layer A6. In other words, the fourth semiconductor layer A4 and the sixth semiconductor layer A6 may be connected integrally.

The first semiconductor layer A1 may include a first channel region CH1 overlapping a first gate electrode G1 of a first transistor T1 described later with reference to FIG. 18, a first source region S1 arranged on one side of the first channel region CH1, and a first drain region D1 arranged on the other side of the first channel region CH1.

The second semiconductor layer A2 may include a second channel region CH2 overlapping a second gate electrode G2 of the second transistor T2 described later with reference to FIG. 18, a second source region S2 arranged on one side of the second channel region CH2, and a second drain region D2 arranged on the other side of the second channel region CH2.

The third semiconductor layer A3 may include a third channel region CH3 overlapping a third gate electrode G3 of a third transistor T3 described later with reference to FIG. 18, a third source region S3 arranged on one side of the third channel region CH3, and a third drain region D3 arranged on the other side of the third channel region CH3.

The fourth semiconductor layer A4 may include a fourth channel region CH4 overlapping a fourth gate electrode G4 of a fourth transistor T4 described later with reference to FIG. 18, a fourth source region S4 arranged on one side of the fourth channel region CH4, and a fourth drain region D4 arranged on the other side of the fourth channel region CH4.

The fifth semiconductor layer A5 may include a fifth channel region CH5 overlapping a fifth gate electrode G5 of a fifth transistor T5 described later with reference to FIG. 18, a fifth source region S5 arranged on one side of the fifth channel region CH5, and a fifth drain region D5 arranged on the other side of the fifth channel region CH5.

The sixth semiconductor layer A6 may include a sixth channel region CH6 overlapping a sixth gate electrode G6 of a sixth transistor T6 described later with reference to FIG. 18, a sixth source region S6 arranged on one side of the sixth channel region CH6, and a sixth drain region D6 arranged on the other side of the sixth channel region CH6.

The first to third semiconductor patterns 1110, 1120, and 1130 may include the same material. In an embodiment, each of the first to third semiconductor patterns 1110, 1120, and 1130 may include an oxide semiconductor material. For example, each of the first to third semiconductor patterns 1110, 1120, and 1130 may include at least one oxide semiconductor material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium CS, cerium (Ce), and zinc (Zn). In an embodiment, each of the first to third semiconductor patterns 1110, 1120, and 1130 may include polysilicon or amorphous silicon.

Referring to FIGS. 17 and 18, the third insulating layer 113 (see FIG. 10) may be disposed on first to third semiconductor patterns 1110, 1120, and 1130, and a second conductive pattern 1210, a third conductive pattern 1220, the fourth conductive pattern 1230, the second write gate line GWLb, the second gate line GRL, the third gate line EML, the fourth gate line GIL, the fifth gate line EMBL, and the first initialization voltage line VAL1 may be disposed on the third insulating layer 113 (see FIG. 10).

Each of the second conductive pattern 1210, the third conductive pattern 1220, and the fourth conductive pattern 1230 may be an isolated shape. For example, the second conductive pattern 1210, the third conductive pattern 1220, and the fourth conductive pattern 1230 may be spaced apart from each other. Each of the second conductive pattern 1210, the third conductive pattern 1220, and the fourth conductive pattern 1230 may be arranged to correspond to each of the first subpixel circuit region SPCA1, the second subpixel circuit region SPCA2, and the third subpixel circuit region SPCA3.

The second conductive pattern 1210 may include the first gate electrode G1 of the first transistor T1 overlapping the first semiconductor layer A1 of the first transistor T1 in a plan view.

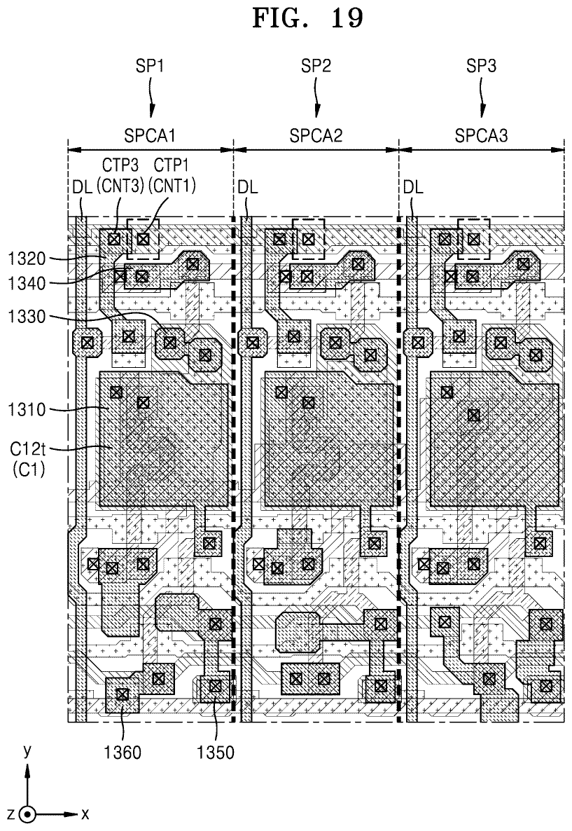

The second conductive pattern 1210 may overlap the first conductive pattern 1050 in a plan view. The second conductive pattern 1210 may include the first electrode C11 of the first capacitor C1 connected to the first node N1 described with reference to FIG. 4. The first electrode C11 of the first capacitor C1 may overlap the second lower electrode C12b of the first capacitor C1 in a plan view. The first capacitor C1 may include the first electrode C11, the second lower electrode C12b, and the second upper electrode C12t described later with reference to FIG. 19. For example, the first gate electrode G1 of the first transistor T1 and the first electrode C11 of the first capacitor C1 may be integrally provided.

The third conductive pattern 1220 may overlap at least a portion of the second semiconductor pattern 1120 in a plan view. The third conductive pattern 1220 may include the second gate electrode G2 of the second transistor T2 overlapping the second semiconductor layer A2 of the second transistor T2 in a plan view.

At least a portion of the fourth conductive pattern 1230 may overlap the reference voltage line VRL (see FIG. 15) in a plan view. The fourth conductive pattern 1230 may be connected to the reference voltage line VRL (see FIG. 15) through a contact hole penetrating at least one insulating layer disposed between the fourth conductive pattern 1230 and the reference voltage line VRL (see FIG. 15). The fourth conductive pattern 1230 may be connected to a fourth connection pattern 1340 described later with reference to FIG. 19. The fourth conductive pattern 1230 may be connected to the second semiconductor pattern (1120, FIG. 17) through the fourth connection pattern 1340.

Each of the second write gate line GWLb, the second gate line GRL, the third gate line EML, the fourth gate line GIL, the fifth gate line EMBL, and the first initialization voltage line VAL1 may extend in the first direction (e.g., the x direction) through the first subpixel circuit region SPCA1, the second subpixel circuit region SPCA2, and the third subpixel circuit region SPCA3.

In a plan view, each of the second write gate line GWLb and the second gate line GRL may be arranged on one side of the second conductive pattern 1210, and each of the third gate line EML, the fourth gate line GIL, the fifth gate line EMBL, and the first initialization voltage line VAL1 may be arranged on the other side of the second conductive pattern 1210. For example, in a plan view, each of the second write gate line GWLb and the second gate line GRL may be arranged on an upper side of the second conductive pattern 1210, and each of the third gate line EML, the fourth gate line GIL, the fifth gate line EMBL, and the first initialization voltage line VAL1 may be arranged on a lower side of the second conductive pattern 1210.

The second write gate line GWLb may be disposed on the first write gate line GWLa to overlap the first write gate line GWLa in a plan view. FIG. 18 illustrates a plan view of the second region R2 (see FIG. 12), showing that the first write gate line GWLa and the second write gate line GWLb are connected by the first contact portion CTP1 located in the first contact hole CNT1. As described above with reference to FIGS. 11 to 14, the first contact portion CTP1 and the first contact hole CNT1 may not be arranged in the first region R1.

The second gate line GRL may overlap at least a portion of the second semiconductor pattern 1120 in a plan view. The second gate line GRL may include the third gate electrode G3 of the third transistor T3 overlapping the third semiconductor layer A3 of the third transistor T3 in a plan view.

The third gate line EML may overlap at least a portion of the first semiconductor pattern 1110 in a plan view. The third gate line EML may include the fifth gate electrode G5 of the fifth transistor T5 overlapping the fifth semiconductor layer A5 of the fifth transistor T5 in a plan view.

The fifth gate line EMBL may overlap at least a portion of the third semiconductor pattern 1130 in a plan view. The fifth gate line EMBL may include the sixth gate electrode G6 of the sixth transistor T6 overlapping the sixth semiconductor layer A6 of the sixth transistor T6 in a plan view.

The fourth gate line GIL may overlap at least a portion of the third semiconductor pattern 1130 in a plan view. The fourth gate line GIL may include the sixth gate electrode G4 of the fourth transistor T4 overlapping the fourth semiconductor layer A4 of the fourth transistor T4 in a plan view.

The second conductive pattern 1210, the third conductive pattern 1220, the fourth conductive pattern 1230, the second write gate line GWLb, the second gate line GRL, the third gate line EML, the fourth gate line GIL, the fifth gate line EMBL, and the first initialization voltage line VAL1 may include the same material. Each of the second conductive pattern 1210, the third conductive pattern 1220, the fourth conductive pattern 1230, the second write gate line GWLb, the second gate line GRL, the third gate line EML, the fourth gate line GIL, the fifth gate line EMBL, and the first initialization voltage line VAL1 may include a conductive material including molybdenum (Mo), aluminum (Al), copper (Cu), titanium (Ti), or the like, and may include a single-layer or multi-layer structure including the aforementioned material.

Referring to FIGS. 18 and 19, the fourth insulating layer 114 (see FIG. 10) may be disposed on the second conductive pattern 1210, the third conductive pattern 1220, the fourth conductive pattern 1230, the second write gate line GWLb, the second gate line GRL, the third gate line EML, the fourth gate line GIL, the fifth gate line EMBL, and the first initialization voltage line VAL1, and the data line DL, a first connection pattern 1310, the second connection pattern 1320, a third connection pattern 1330, the fourth connection pattern 1340, a fifth connection pattern 1350, and a sixth connection pattern 1360 may be disposed on the fourth insulating layer 114 (see FIG. 10).

Each of the data line DL, the first connection pattern 1310, the second connection pattern 1320, the third connection pattern 1330, the fourth connection pattern 1340, the fifth connection pattern 1350, and the sixth connection pattern 1360 may be arranged to correspond to each of the first subpixel circuit region SPCA1, the second subpixel circuit region SPCA2, and the third subpixel circuit region SPCA3.

The data line DL may extend along the second direction (e.g., the y direction) intersecting the first direction (e.g., the x direction). The data line DL may be electrically connected to the second drain region D2 (see FIG. 17) of the second semiconductor layer A2 of the second transistor T2 through a contact hole penetrating at least one insulating layer disposed between the second semiconductor layer A2 and the data line DL. For example, the data lines DL arranged in the first subpixel circuit region SPCA1, the second subpixel circuit region SPCA2, and the third subpixel circuit region SPCA3, may be electrically connected to the second transistor T2 of the first subpixel SP1, the second transistor T2 of the second subpixel SP2, and the second transistor T2 of the third subpixel SP3, respectively.

The first connection pattern 1310 may be connected to the first semiconductor pattern 1110 (see FIG. 17) through a contact hole penetrating at least one insulating layer disposed between the first connection pattern 1310 and the first semiconductor pattern (1110, FIG. 17). For example, the first connection pattern 1310 may be connected to the first source region S1 (see FIG. 17) of the first semiconductor layer A1 of the first transistor T1 through a contact hole.

The first connection pattern 1310 may be connected to the third semiconductor pattern 1130 (see FIG. 17) through a contact hole penetrating at least one insulating layer disposed between the first connection pattern 1310 and the first semiconductor pattern 1130 (see FIG. 17). For example, the first connection pattern 1310 may be connected to the sixth drain region D6 (see FIG. 17) of the sixth semiconductor layer A6 of the sixth transistor T6 through a contact hole.

The first connection pattern 1310 may include the second upper electrode C12t of the first capacitor C1. The second upper electrode C12t of the first capacitor C1 may be connected to the second lower electrode C12b of the first capacitor C1 by a contact hole penetrating at least one insulating layer disposed between the second upper electrode C12t of the first capacitor C1 and the second lower electrode C12b of the first capacitor C1. The second upper electrode C12t of the first capacitor C1 may overlap the first electrode C11 of the first capacitor C1 in a plan view.

The first connection pattern 1310 may connect the first semiconductor layer A1, the sixth semiconductor layer A6, the second upper electrode C12t of the first capacitor C1, and the second lower electrode C12b of the first capacitor C1. The first connection pattern 1310 may correspond to the connection conductive pattern CMP described with reference to FIG. 10.

The second connection pattern 1320 may connect the second gate electrode G2 of the second transistor T2 and the second write gate line GWLb. The second connection pattern 1320 may be connected to the second write gate line GWLb through the third contact hole CNT3 penetrating at least one insulating layer disposed between the second connection pattern 1320 and the second write gate line GWLb. For example, the second connection pattern 1320 may be connected to the second write gate line GWLb through the third contact portion CTP3 located in the third contact hole CNT3. The third contact portion CTP3 may be disposed between the second connection pattern 1320 and the second write gate line GWLb.

FIG. 19 illustrates a plan view of the second region R2 (see FIG. 12), showing that the third contact portion CTP3 and the first contact portion CTP1 are arranged along the first direction (e.g., x direction or row direction) in second region R2. As described above with reference to FIGS. 11 to 14, the first contact portion CTP1 and the first contact hole CNT1 may not be arranged in the first region R1, and therefore, the first contact portion CTP1 may not be arranged in the region along the first direction from the third contact portion CTP3 in the first region R1.

The third connection pattern 1330 may connect the second semiconductor pattern 1120 and the second conductive pattern 1210. The third connection pattern 1330 may connect the second drain region D2 (see FIG. 17) of the second semiconductor layer A2 of the second transistor T2, the third drain region D3 (see FIG. 17) of the third semiconductor layer A3 of the third transistor T3, and the first gate electrode G1 of the first transistor T1. The third connection pattern 1330 may connect the second drain region D2 (see FIG. 17) of the second semiconductor layer A2 of the second transistor T2, the third drain region D3 (see FIG. 17) of the third semiconductor layer A3 of the third transistor T3, and the first electrode C11 of the first capacitor C1.

The fourth connection pattern 1340 may be connected to the fourth conductive pattern 1230 and the second semiconductor pattern 1120 (see FIG. 17) through contact holes, and the fourth conductive pattern 1230 may be connected to the reference voltage line VRL. For example, the fourth connection pattern 1340 and the fourth conductive pattern 1230 may connect the reference voltage line VRL and the third semiconductor layer A3 of the third transistor T3.

The fifth connection pattern 1350 may be a pattern arranged to be capable of connecting the repair line RL (see FIG. 15) and the subpixel circuit, when a defect occurs in a signal line or voltage line included in the subpixel circuit. For example, the fifth connection pattern 1350 is connected to a repair pattern 1060 and the third semiconductor pattern 1130 illustrated in FIG. 16, and when a defect occurs in a signal line or a voltage line, the repair pattern 1060 may be arranged to be connected by joining with the repair line RL (see FIG. 15). The repair pattern 1060 and the first conductive pattern 1050 may be in the same layer.

The sixth connection pattern 1360 arranged in the first subpixel circuit region SPCA1 may connect the first initialization voltage line VAL1 and the fourth source area S4 (see FIG. 17) of the fourth semiconductor layer A4 of the fourth transistor T4 of the first subpixel circuit region SPCA1. The sixth connection pattern 1360 arranged in the second subpixel circuit region SPCA2 may connect the second initialization voltage line VAL2 and the fourth source area S4 (see FIG. 17) of the fourth semiconductor layer A4 of the fourth transistor T4 of the second subpixel circuit region SPCA2. The sixth connection pattern 1360 arranged in the third subpixel circuit region SPCA3 may connect the third initialization voltage line VAL3 and the fourth source area S4 (see FIG. 17) of the fourth semiconductor layer A4 of the fourth transistor T4 of the third subpixel circuit region SPCA3.

The data line DL, the first connection pattern 1310, the second connection pattern 1320, the third connection pattern 1330, the fourth connection pattern 1340, the fifth connection pattern 1350, and the sixth connection pattern 1360 may include the same material. The data line DL, the first connection pattern 1310, the second connection pattern 1320, the third connection pattern 1330, the fourth connection pattern 1340, the fifth connection pattern 1350, and the sixth connection pattern 1360 may include a conductive material including molybdenum (Mo), aluminum (Al), copper (Cu), titanium (Ti), or the like, and may include a single-layer or multi-layer structure including the aforementioned materials.

According to one or more embodiments, a display device having improved display quality and an electronic device including the same may be provided. However, the scope of the disclosure is not limited by such effects.

The present embodiments have been described with reference to an embodiment shown in the drawings, but this is merely an example, and one of ordinary skill in the art will understand that various modifications and variations of the embodiment are possible therefrom. Therefore, the protection scope of the present embodiments should be determined by the attached claims.

What is claimed is:

1. A display device comprising:
a substrate comprising a display area and a non-display area, wherein the display area includes a plurality of first regions and a plurality of second regions, and the non-display area surrounds at least a portion of the display area;
a gate driving circuit in the non-display area;
a first write gate line extending in a first direction and electrically connected to the gate driving circuit;
a second write gate line extending in the first direction through the first regions and the second regions and overlapping the first write gate line in a plan view;
first contact portions disposed between the first write gate line and the second write gate line, and electrically connecting the first write gate line to the second write gate line; and
pixels including subpixels arranged in each of the first regions and each of the second regions of the display area, each of the subpixels being electrically connected to the second write gate line,
wherein the first contact portions are arranged in the second regions, not in the first regions.

2. The display device of claim 1, wherein
the second regions are spaced apart from the non-display area in the first direction, and at least one of the first regions is located between the non-display area and the plurality of second regions in the first direction.

3. The display device of claim 2, wherein
the first regions and the second regions are arranged alternately along the first direction.

4. The display device of claim 1, wherein
each of the pixels includes a first subpixel, a second subpixel, and a third subpixel,
a first subpixel circuit region, a second subpixel circuit region, and a third subpixel circuit region are arranged adjacent to each other in the first direction, a first subpixel circuit of the first subpixel is arranged in the first subpixel circuit region, a second subpixel circuit of the second subpixel is arranged in the second subpixel circuit region, and a third subpixel circuit of the third subpixel is arranged in the third subpixel circuit region, and
the first contact portions are arranged to correspond to each of the first subpixel circuit region, the second subpixel circuit region, and the third subpixel circuit region in each of the second regions.

5. The display device of claim 1, wherein
a width of one of the first regions in the first direction is greater than a width of one of the second regions in the first direction.

6. The display device of claim 1, wherein
a total number of pixels in each of the first regions is greater than a total number of pixels in each of the second regions.

7. The display device of claim 1, further comprising
an insulating layer disposed between the first write gate line and the second write gate line,
wherein the insulating layer defines contact holes therethrough, and the first contact portions are arranged in the contact holes, respectively.

8. The display device of claim 1, wherein
the first write gate line includes a first lower write gate line and a first upper write gate line, and the first upper write gate line is disposed on the first lower write gate line and overlaps the first lower write gate line in the plan view.

9. The display device of claim 8, further comprising
second contact portions disposed between the first lower write gate line and the first upper write gate line, and electrically connecting the first lower write gate line to the first upper write gate line,
wherein the second contact portions are arranged in each of the first regions and each of the second regions,

10. The display device of claim 8, wherein
the second write gate line is disposed above the first write gate line.

11. The display device of claim 8, wherein
the second write gate line is disposed below the first write gate line.

12. The display device of claim 1, wherein
each of the subpixels includes a data write transistor to which a data voltage is applied, and
the second write gate line is electrically connected to a gate electrode of the data write transistor.

13. The display device of claim 12, further comprising
a data line extending along a second direction intersecting the first direction,
wherein the data line is electrically connected to the data write transistor.

14. A display device comprising:
a substrate comprising a display area and a non-display area surrounding at least a portion of the display area;
a gate driving circuit in the non-display area;
a first write gate line extending in a first direction and electrically connected to the gate driving circuit;
a second write gate line extending in the first direction and overlapping the first write gate line in a plan view;
first contact portions disposed between the first write gate line and the second write gate line, and electrically connecting the first write gate line to the second write gate line; and
pixels arranged in the display area, each including subpixels, each of the subpixels being electrically connected to the second write gate line,
wherein a total number of the first contact portions is less than a total number of the subpixels electrically connected to the second write gate line.

15. The display device of claim 14, wherein
the display area includes a plurality of first regions and a plurality of second regions,
at least one of the pixels is arranged in each of the first regions and each of the second regions,
each of the first write gate line and the second write gate line extends through the first regions and the second regions, and
the first contact portions are arranged in the second regions, not in the first regions,

16. The display device of claim 15, wherein
the second regions are spaced apart from the non-display area in the first direction, and at least one of the first regions is located between the non-display area and the plurality of second regions in the first direction.

17. The display device of claim 15, wherein
the first regions and the second regions are arranged alternately along the first direction.

18. The display device of claim 15, wherein
each of the pixels includes a first subpixel, a second subpixel, and a third subpixel,
a first subpixel circuit region, a second subpixel circuit region, and a third subpixel circuit region are arranged adjacent to each other in the first direction, a first subpixel circuit of the first subpixel is arranged in the first subpixel circuit region, a second subpixel circuit of the second subpixel is arranged in the second subpixel circuit region, and a third subpixel circuit of the third subpixel is arranged in the third subpixel circuit region, and
the first contact portions are arranged to correspond to each of the first subpixel circuit region, the second subpixel circuit region, and the third subpixel circuit region in each of the second regions.

19. An electronic device comprising:
a processor; and
a display device including a controller configured to receive a control signal from the processor and output a scan control signal based on the control signal,
wherein the display device comprises:
a substrate comprising a display area and a non-display area, where the display area includes first regions and second regions, and the non-display area surrounds at least a portion of the display area;
a gate driving circuit arranged in the non-display area and configured to receive the scan control signal;
a first write gate line extending in a first direction and electrically connected to the gate driving circuit;
a second write gate line extending in the first direction through the first regions and the second regions and overlapping the first write gate line in a plan view;
first contact portions disposed between the first write gate line and the second write gate line, and electrically connecting the first write gate line to the second write gate line; and
pixels including subpixels arranged in each of the first regions and the second regions of the display area, each of the subpixels being electrically connected to the second write gate line,
wherein the first contact portions are arranged in the second regions, not in the first regions.
